(19) United States
(12) Patent Application Publication
(10) Pub. No.: US 2013/0137216 A1
(43) Pub. Date: May 30, 2013

(54) METHOD OF MANUFACTURING SEMICONDUCTOR DEVICE HAVING PLURAL SEMICONDUCTOR CHIPS STACKED ONE ANOTHER

(71) Applicant: ELPIDA MEMORY, INC., Tokyo (JP)

(72) Inventors: Youkou ITO, Tokyo (JP); Shinichi SAKURADA, Tokyo (JP)

(73) Assignee: ELPIDA MEMORY, INC., Tokyo (JP)

(21) Appl. No.: 13/683,245

(22) Filed: Nov. 21, 2012

(30) Foreign Application Priority Data
Nov. 28, 2011 (JP) 2011-258950
Oct. 26, 2012 (JP) 2012-236607

(51) Int. Cl. H01L 21/56; H01L 23/00

(52) U.S. Cl. CPC H01L 21/563; H01L 24/81
USPC 438/108; 438/109

(57) ABSTRACT

Disclosed herein is a method of manufacturing a semiconductor device that includes stacking a plurality of semiconductor chips to form a first chip laminated body, providing an underfill material to fill gaps between the semiconductor chips so that a fillet portion is formed around the first chip laminated body, and trimming the fillet portion to form a second chip laminated body.

### BACKGROUND OF THE INVENTION

1. Field of the Invention

The present invention relates to a method of manufacturing a semiconductor device, and more particularly to a method of manufacturing a semiconductor device having a plurality of semiconductor chips stacked one another.

2. Description of Related Art

In recent years, the integration density of semiconductor chips has been increasing year after year, leading to an increase in the size of the chips and promoting miniaturization of wiring and multi-layer structures. Meanwhile, in order to realize high-density mounting, the semiconductor devices need to be made smaller in size and thinner.

To meet such a need, a technique called MCP (Multi Chip Package) has been developed of mounting a plurality of semiconductor chips on one package substrate in a high-density manner.

Especially, the semiconductor device called CoC (Chip on Chip) type has gained attention. The semiconductor device of a CoC type includes a stacked body that is constituted by a plurality of semiconductor chips stacked one another. In the semiconductor device of the CoC type, each of the semiconductor chips has a thickness of 50 μm or less, for example, and has penetration electrodes called TSV (Through Silicon Via).

Japanese Patent Application Laid-Open No. 2010-251347 discloses a method of manufacturing a CoC-type semiconductor device by stacking a plurality of semiconductor chips while connecting penetration electrodes of the semiconductor chips, forming a first sealing resin layer (underfill material) to cover the peripheries of a plurality of semiconductor chips stacked (referred to as a “chip laminated body,” hereinafter) and fill the gaps between the semiconductor chips, and connecting and fixing the chip laminated body, on which the first sealing resin layer is formed, on a package substrate on which predetermined wirings are formed.

However, according to the method of manufacturing the semiconductor device disclosed in Japanese Patent Application Laid-Open No. 2010-251347, around the chip stacked body filled with the underfill material (first sealing resin layer), fillets would be formed due to the underfill material. Depending on how the fillets have spread, the external dimensions of the chip laminated body (which is, in other words, a structure made up of the underfill material and the chip laminated body), on which the underfill material has been formed, become uneven, making it impossible to manage the external dimensions.

If the above fillets are large, there is concern that stress may be applied to the thin semiconductor chips, which constitute the chip laminated body, as the fillet portions swell and contract each time the chip laminated body is heated in a process of mounting the chip laminated body, on which the underfill material is formed, on the package substrate, and in subsequent processes.

If the stress is applied to the chip laminated body, there is concern that cracks may appear in the chips, or that a bump joint area where the semiconductor chips are connected together may break up.

### SUMMARY

In one aspect of the present invention, there is provided a method of manufacturing a semiconductor device that includes: stacking a plurality of semiconductor chips to form a first chip laminated body; providing an underfill material to fill gaps between the semiconductor chips so that a fillet portion is formed around the first chip laminated body; and trimming the fillet portion to form a second chip laminated body.

In another aspect of the present invention, there is provided a method for manufacturing a semiconductor device that includes: stacking a plurality of semiconductor chips to form gaps between adjacent ones of the semiconductor chips; providing a sealing resin to the gaps between adjacent ones of the semiconductor chips so that a part of the sealing resin protrudes from a side surface of at least one of the semiconductor chips; and trimming the protruded part of the sealing resin to form a flat surface.

According to the above aspects of the present invention, it is possible to prevent variation in the outer shape of the second chip laminated body because the fillet portion is trimmed. Therefore, it becomes possible to manage the external dimensions of the second chip laminated body.

As the external dimensions of the second chip laminated body become stable, the resistance of the second chip laminated body can be improved against the stress resulting from an external force at the time of handling.

Furthermore, because the fillet portion is trimmed, it is possible to reduce the stress of the underfill material at a time when the second chip laminated body with the underfill material is heated.

Therefore, it is possible to prevent the breakage or chip cracking of the semiconductor chips that may be made thin (e.g. semiconductor chips with a thickness of 50 μm or less, for example), and the breaking of the connection portions (joint areas) between the semiconductor chips.

Furthermore, the second chip laminated body can be smaller in size because the fillet portion is trimmed. Therefore, the semiconductor device employing the second chip laminated body can be smaller in size.

### BRIEF DESCRIPTION OF THE DRAWINGS

FIG. 1 is a cross-sectional view of a semiconductor device according to the first embodiment of the present invention;

FIGS. 2 to 5, 6A, 6B, 7A, 7B, 8, 9, 10A, 10B, and 11 to 16 are diagrams illustrating a process of manufacturing the semiconductor device according to the first embodiment of the present invention;

FIG. 17 is a cross-sectional view of a semiconductor device according to the second embodiment of the present invention;

FIG. 18 is a cross-sectional view of a semiconductor device according to the third embodiment of the present invention;

FIG. 19 is a cross-sectional view of a semiconductor device according to the fourth embodiment of the present invention; and

FIGS. 20 to 24 are diagrams illustrating a process of manufacturing the semiconductor device according to the fourth embodiment of the present invention.

### DETAILED DESCRIPTION OF THE EMBODIMENTS

Hereinafter, with reference to the accompanying drawings, embodiments of the present invention will be described in detail. Incidentally, the drawings used in the following description are for illustrating the configurations of the embodiments of the present invention. The size, thickness, dimensions, and other factors of each of the sections shown in the drawings may be different from the dimensional relationship of an actual semiconductor device.

### First Embodiment

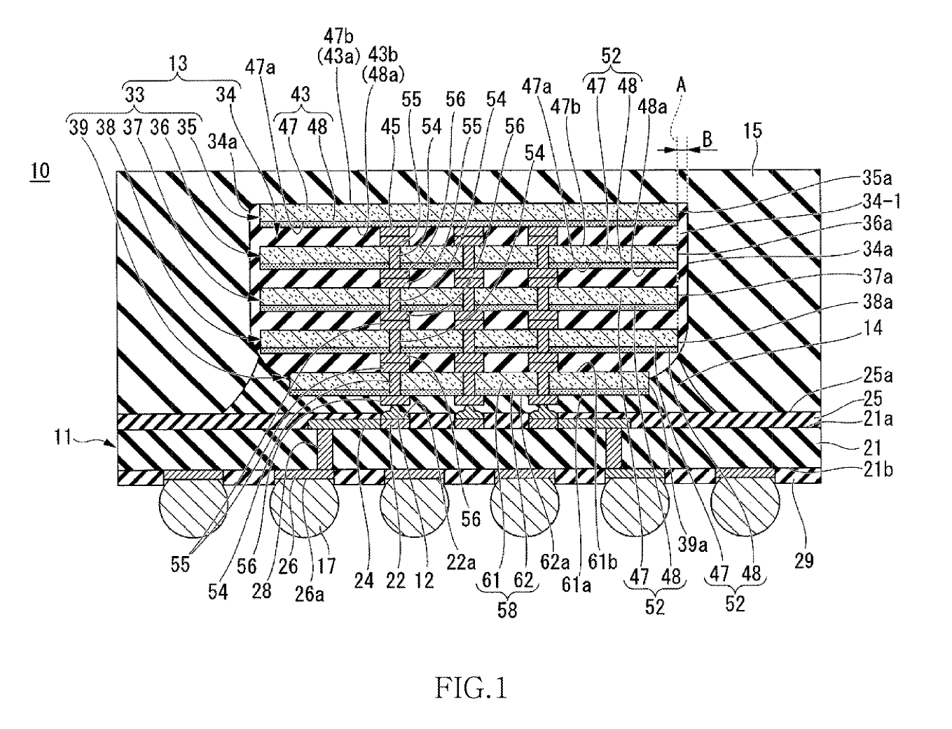

Referring now to FIG. 1, a semiconductor device 10 of the first embodiment is a semiconductor device of a CoC (Chip on Chip) type. The semiconductor device 10 includes a wiring substrate 11, wire bumps 12, a chip laminated body 13 with an underfill material, a first sealing resin 14, a second sealing resin 15, and external connection terminals 17.

The wiring substrate 11 includes a wiring substrate body 21, connection pads 22, wirings 24, a first solder resist 25, external connection pads 26, penetration electrodes 28, and a second solder resist 29.

The wiring substrate body 21 is an insulating substrate that is in the shape of a rectangle, and has a flat surface 21a (principal surface of the wiring substrate 11), and a back surface 21b. For the wiring substrate body 21, for example, a glass epoxy board may be used.

The connection pads 22 are provided in a central portion of the surface 21a of the wiring substrate body 21. The connection pads 22 are so disposed as to face surface bump electrodes 56 of a second semiconductor chip 39, which constitutes the chip laminated body 13 with the underfill material.

Each of the connection pads 22 includes a bump mounting surface 22a, which faces an associated one of the surface bump electrodes 56 of the second semiconductor chip 39.

The wirings 24 are rewired lines, and are connected to the connection pads 22. The first solder resist 25 is provided on the surface 21a of the wiring substrate body 21 so as to cover the wirings 24. The first solder resist 25 allows the bump mounting surface 22a of the connection pads 22 to be exposed.

The external connection pads 26 are provided on the back surface 21b of the wiring substrate body 21. Each of the external connection pads 26 includes a terminal mounting surface 26a.

The penetration electrodes 28 penetrates the wiring substrate body 21, each of which is positioned between an associated one of the wirings 24 and an associated one of the external connection pads 26. One end of each of the penetration electrodes 28 is connected to the associated one of the wirings 24, and the other end to the associated one of the external connection pads 26.

The second solder resist 29 is provided on the back surface 21b of the wiring substrate body 21 so that the terminal mounting surface 26a of the external connection pads 26 are exposed.

The wire bumps 12 are disposed on the bump mounting surface 22a of the connection pads 22. For the wire bumps 12, for example, an Au bump may be used.

The chip laminated body 13 with the underfill material includes a chip laminated body 33 and an underfill material 34.

The chip laminated body 33 is so formed as to have a first semiconductor chip 35 and second semiconductor chips 36 to 39, which are a plurality of semiconductor chips.

The first semiconductor chip 35 is a semiconductor chip that is disposed on a top layer in the situation (i.e. that shown in FIG. 1) where the chip laminated body 13 with the underfill material is mounted on the wiring substrate 11.

For example, for the first semiconductor chip 35, a semiconductor memory chip may be used. In this case, as the first semiconductor chip 35, for example, a DRAM (Dynamic Random Access Memory) may be used.

The following describes an example of using the DRAM as the first semiconductor chip 35.

The first semiconductor chip 35 includes a first chip body 43, which has one flat surface 43a and the other surface 43b; and a plurality of surface bump electrodes 45 (first bump electrodes). The first chip body 43 is in the shape of a rectangle, and includes a semiconductor substrate 47 and a circuit element layer 48.

The semiconductor substrate 47 is a substrate that has been made thin (with a thickness of 50 μm or less, for example). For the semiconductor substrate 47, for example, a single-crystal silicon substrate may be used. The semiconductor substrate 47 has a surface 47a, which is a flat plane, and a back surface 47b.

The circuit element layer 48 is formed on the surface 47a of the semiconductor substrate 47. The circuit element layer 48 includes transistors, which are not shown in the diagram, a plurality of interlayer insulating films stacked, and wiring patterns (vias and wiring), which are formed on the plurality of the interlayer insulating films. On the circuit element layer 48, a DRAM element (not shown) is formed.

The surface bump electrodes 45 are provided on the surface 48a of the circuit element layer 48 (or on the other surface 43b of the first chip body 43). The surface bump electrodes 45 are electrically connected to the DRAM element formed on the circuit element layer 48.

After the chip laminated body 13 with the underfill material is mounted on the wiring substrate 11, the surface bump electrodes 45 face the surface 21a of the wiring substrate body 21.

For the surface bump electrodes 45, for example, a Cu/Ni/Au laminated film may be used: the Cu/Ni/Au laminated film is made by sequentially stacking a Cu film, a Ni film, and an Au film on the surface 48a of the circuit element layer 48. The Cu/Ni/Au laminated film may be made by plating.

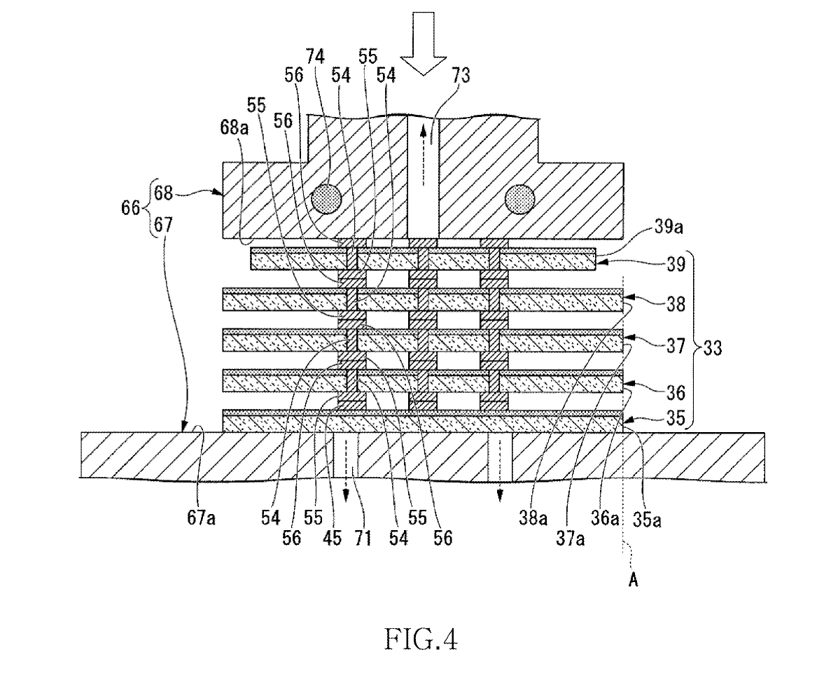

The first semiconductor chip 35 is a semiconductor chip that is disposed on a bottom layer in a process described later with reference to FIG. 4 (or a process of forming the chip laminated body 33).

The second semiconductor chip 36 is disposed immediately below the first semiconductor chip 35. For the second semiconductor chip 36, for example, a semiconductor memory chip may be used. In this case, as the second semiconductor chip 36, for example, a DRAM (Dynamic Random Access Memory) may also be used.

The following describes an example of using the DRAM as the second semiconductor chip 36.

The second semiconductor chip 36 includes a second chip body 52, a plurality of penetration electrodes 54, a plurality of back-surface bump electrodes 55 (one second bump electrode), and a plurality of surface bump electrodes 56 (the other second bump electrode that is exposed from the underfill material 34).

The second chip body 52 has the same configuration as the first chip body 43 provided on the first semiconductor chip 35. That is, the second chip body 52 includes a semiconductor substrate 47 and a circuit element layer 48. Moreover, the outer shape of the second chip body 52 is equal in size to that of the rectangular first chip body 43.

The penetration electrodes 54 are so provided as to pass through a portion of the second chip body 52 that is positioned below the surface bump electrodes 45. The penetration electrodes 54 are electrically connected to a DRAM element provided on the circuit element layer 48 of the second chip body 52.

The back-surface bump electrodes 55 are provided at one end of the penetration electrodes 54. The back-surface bump electrodes 55 are connected (bonded) to the surface bump electrodes 45 of the first semiconductor chip 35. That is, the first and second semiconductor chips 35 and 36 are flip-chip mounted.

For the back-surface bump electrodes 55, for example, a Cu/SnAg laminated film may be used: the Cu/SnAg laminated film is made by sequentially stacking a Cu film and a SnAG solder film on one end of the penetration electrodes 54. The Cu/SnAg laminated film may be formed by plating.

The surface bump electrodes 56 are provided on the other ends of the penetration electrodes 54 (or on the surface 48a of the circuit element layer 48). Therefore, the surface bump electrodes 56 are electrically connected to the DRAM element formed on the circuit element layer 48 and the back-surface bump electrodes 55 via the penetration electrodes 54.

After the chip laminated body 13 with the underfill material is mounted on the wiring substrate 11, the surface bump electrodes 56 face the surface 21a of the wiring substrate body 21.

For the surface bump electrodes 56, for example, a Cu/Ni/Au laminated film may be used: the Cu/Ni/Au laminated film is made by sequentially stacking a Cu film, a Ni film, and an Au film on the surface 48a of the circuit element layer 48. The Cu/Ni/Au laminated film may be made by plating.

The second semiconductor chip 37 is disposed immediately below the second semiconductor chip 36. The second semiconductor chip 37 has the same configuration as the second semiconductor chip 36.

The back-surface bump electrodes 55 of the second semiconductor chip 37 are connected (bonded) to the surface bump electrodes 56 of the second semiconductor chip 36. That is, the second semiconductor chips 36 and 37 are flip-chip mounted.

Accordingly, the second semiconductor chip 37 is electrically connected to the first and second semiconductor chips 35 and 36.

After the chip laminated body 13 with the underfill material is mounted on the wiring substrate 11, the surface bump electrodes 56 of the second semiconductor chip 37 face the surface 21a of the wiring substrate body 21.

The second semiconductor chip 38 is disposed immediately below the second semiconductor chip 37. The second semiconductor chip 38 has the same configuration as the second semiconductor chip 36.

The back-surface bump electrodes 55 of the second semiconductor chip 38 are connected (bonded) to the surface bump electrodes 56 of the second semiconductor chip 37. That is, the second semiconductor chips 37 and 38 are flip-chip mounted.

Accordingly, the second semiconductor chip 38 is electrically connected to the first and second semiconductor chips 35, 36 and 37.

After the chip laminated body 13 with the underfill material is mounted on the wiring substrate 11, the surface bump electrodes 56 of the second semiconductor chip 38 face the surface 21a of the wiring substrate body 21.

The second semiconductor chip 39 is disposed immediately below the second semiconductor chip 38. The second semiconductor chip 39 is a semiconductor chip that is disposed on a bottom layer in the situation (i.e. that shown in FIG. 1) where the chip laminated body 13 with the underfill material is mounted on the wiring substrate 11.

For the second semiconductor chip 39, for example, a semiconductor chip having an interface function between the semiconductor memory chips and outside may be used. The following describes an example of using the semiconductor interface chip as the second semiconductor chip 39.

The second semiconductor chip 39 is formed in the same way as the second semiconductor chip 36 except that, instead of the second chip body 52 provided on the second semiconductor chip 36, a second chip body 58 is provided.

The second chip body 58 is in the shape of a rectangle. The outer shape of the second chip body 58 is smaller in size than the second chip body 52. The second chip body 58 includes a semiconductor substrate 61 and a circuit element layer 62.

The semiconductor substrate 61 is a substrate that has been made thin (with a thickness of 50 μam or less, for example). For the semiconductor substrate 61, for example, a single-crystal silicon substrate may be used. The semiconductor substrate 61 has a surface 61a, which is a flat plane, and a back surface 61b.

The circuit element layer 62 is formed on the surface 61a of the semiconductor substrate 61. The circuit element layer 62 includes transistors, which are not shown in the diagram, a plurality of interlayer insulating films stacked, and wiring patterns (vias and wiring), which are formed on the plurality of the interlayer insulating films. The circuit element layer 62 includes an interface element (not shown).

The back-surface bump electrodes 55 of the second semiconductor chip 39 are provided at one end of the penetration electrodes 54, which are positioned on the back surface 61b's side of the semiconductor substrate 61. The back-surface bump electrodes 55 of the second semiconductor chip 39 are connected (bonded) to the surface bump electrodes 56 of the second semiconductor chip 38. That is, the second semiconductor chips 38 and 39 are flip-chip mounted.

The surface bump electrodes 56 of the second semiconductor chip 39 are provided at the other end of the penetration electrodes 54, which are positioned on the surface 62a's side of the circuit element layer 62. The surface bump electrodes 56 of the second semiconductor chip 39 are electrically connected to an interface element formed on the circuit element layer 62.

The surface bump electrodes 56 of the second semiconductor chip 39 are so disposed as to face the bump mounting surface 22a of the connection pads 22.

The surface bump electrodes 56 of the second semiconductor chip 39 are electrodes that functions as an external connection terminal of the chip laminated body 13 with the underfill material. The surface bump electrodes 56 are electrically connected to the connection pads 22 of the wiring substrate 11 via the wire bumps 12.

Accordingly, the chip laminated body 13 with the underfill material is flip-chip mounted on the wiring substrate 11.

The second semiconductor chip 39 is a semiconductor chip that mediates the exchange of information between the semiconductor memory chips 35 to 38, which are stacked and mounted on the second semiconductor chip 39, and the wiring substrate 11.

The second semiconductor chip 39 is a semiconductor chip that is disposed on a top layer in a process described later with reference to FIG. 4 (or a process of forming the chip laminated body 33).

Side surfaces 35a, 36a, 37a, and 38a of the first and second semiconductor chips 35 to 38, which make up the chip laminated body 33, are flush with a plane A, which is perpendicular to the surface 21a of the wiring substrate body 21.

In other words, the side surfaces 35a, 36a, 37a, and 38a of the first and second semiconductor chips 35 to 38 are disposed on the same plane A.

Between the first and second semiconductor chips 35 to 38 that are stacked and mounted, narrow gaps are formed. Between the second semiconductor chip 39, which constitutes the chip laminated body 33, and the wiring substrate 11, a gap is formed.

The underfill material 34 fills the gaps between the first and second semiconductor chips 35 to 39, which make up the chip laminated body 33. Moreover, the underfill material 34 is so disposed as to cover the side surfaces 35a, 36a, 37a, and 38a of the first and second semiconductor chips 35 to 38.

The underfill material 34 allows the surface bump electrodes 56 and the surface 62a of the circuit element layer 62, which constitute the second semiconductor chip 39, to be exposed.

The underfill material 34 is formed by capillary phenomenon. A fillet portion 34-1, which is disposed on four side walls of the chip laminated body 33, is trimmed. The trimmed fillet portion 34-1 is narrower in width than the fillet portion not trimmed. The trimmed fillet portion 34-1 also has a plane 34a, which runs parallel to the side surfaces 35a, 36a, 37a, 38a, and 39a of the first and second semiconductor chips 35 to 39.

Four planes 34a are provided around the chip laminated body 33 so as to face each of the side walls (four side walls) of the chip laminated body 33.

The planes 34a of the underfill material 34 are disposed near the side surfaces 35a, 36a, 37a, and 38a of the first and second semiconductor chips 35 to 38.

The distance B from the side surfaces 35a, 36a, 37a, and 38a (plane A) of the first and second semiconductor chips 35 to 38 to the plane 34a of the underfill material 34 may be 50 μm, for example.

In that manner, the fillet portion 34-1 is trimmed. The underfill material 34 having four planes 34a is also provided: the four planes 34a run parallel to the side surfaces 35a, 36a, 37a, 38a, 39a of the first and second semiconductor chips 35 to 39, and are disposed near the side surfaces 35a, 36a, 37a, and 38a of the first and second semiconductor chips 35 to 38. Therefore, it is possible to prevent the shape of the fillet portion 34-1 from varying. As a result, it is possible to prevent variation in the outer shape of the chip laminated body 13 with the underfill material, which can occur due to variation in the shape of the fillet portion 34-1.

Therefore, it becomes possible to manage the external dimensions of the chip laminated body 13 with the underfill material.

As the external dimensions of the chip laminated body 13 with the underfill material become stable, the resistance of the chip laminated body 13 with the underfill material can be improved against the stress resulting from an external force at the time of handling.

Furthermore, the fillet portion 34-1 is trimmed. Therefore, it is possible to reduce the stress of the underfill material 34 at a time when the chip laminated body 13 with the underfill material is heated.

Therefore, it is possible to prevent the breakage (chip cracking) of the first and second semiconductor chips 35 to 39 that are made thin (e.g. semiconductor chips with a thickness of 50 μm or less, for example), and the breaking of the connection portions (joint areas) between the first and second semiconductor chips 35 to 39.

For the underfill material 34, for example, thermosetting resin (or more specifically, thermosetting epoxy resin, for example) may be used.

The first sealing resin 14 fills the gap between the chip laminated body 13 with the underfill material (or more specifically, the second semiconductor chip 39) and the wiring substrate 11. The first sealing resin 14 is so disposed as to cover the second semiconductor chip 39, which is exposed from the underfill material 34.

In this manner, the first sealing resin 14 reinforces the connection portion (joint area) between the chip laminated body 13 with the underfill material and the wiring substrate 11.

For the first sealing resin 14, for example, NCP (Non-Conductive Paste) may be used.

The second sealing resin 15 is provided on an upper surface 25a (principal surface of the wiring substrate 11) of the first solder resist 25, which makes up the wiring substrate 11, so as to cover the chip laminated body 13 with the underfill material and the first sealing resin 14. An upper surface 15a of the second sealing resin 15 is a flat plane.

For the second sealing resin 15, for example, mold resin may be used.

The external connection terminals 17 are provided on the terminal mounting surface 26a of the external connection pads 26. The external connection terminals 17 are terminal that are connected to pads of a board when the semiconductor device 10 is mounted on the board such as a motherboard.

For the external connection terminals 17, for example, a solder ball may be used.

According to the semiconductor device of the first embodiment, the chip laminated body 13 with the underfill material is provided, which includes the chip laminated body 33, on which the first and second semiconductor chips 35 to 38 are stacked and mounted; and the underfill material 34, whose fillet portion 34-1 is trimmed and which includes the four planes 34 that run parallel to the side surfaces 35a, 36a, 37a, 38a, 39a of the first and second semiconductor chips 35 to 39 and are disposed near the side surfaces 35a, 36a, 37a, and 38a of the first and second semiconductor chips 35 to 38. Therefore, it is possible to curb variation in the shape of the fillet portion 34-1. Asa result, it is possible to prevent variation in the outer shape of the chip laminated body 13 with the underfill material, which can occur due to variation in the shape of the fillet portion 34-1.

Therefore, it becomes possible to manage the external dimensions of the chip laminated body 13 with the underfill material.

As the external dimensions of the chip laminated body 13 with the underfill material become stable, the resistance of the chip laminated body 13 with the underfill material can be improved against the stress resulting from an external force at the time of handling.

Furthermore, the fillet portion 34-1 is trimmed. Therefore, it is possible to reduce the stress of the underfill material 34 at a time when the chip laminated body 13 with the underfill material is heated.

Therefore, it is possible to prevent the breakage (chip cracking) of the first and second semiconductor chips 35 to 39 that are made thin (e.g. semiconductor chips with a thickness of 50 μm or less, for example), and the breaking of the connection portions (joint areas) between the first and second semiconductor chips 35 to 39.

Since the fillet portion 34-1 is trimmed, the chip laminated body 13 with the underfill material can be made smaller in size. As a result, the wiring substrate 11 on which the chip laminated body 13 with the underfill material is mounted can be made smaller in size.

Furthermore, as the wiring substrate 11 becomes smaller in size, the semiconductor device 10 having the wiring substrate 11 and the chip laminated body 13 with the underfill material can also be smaller in size.

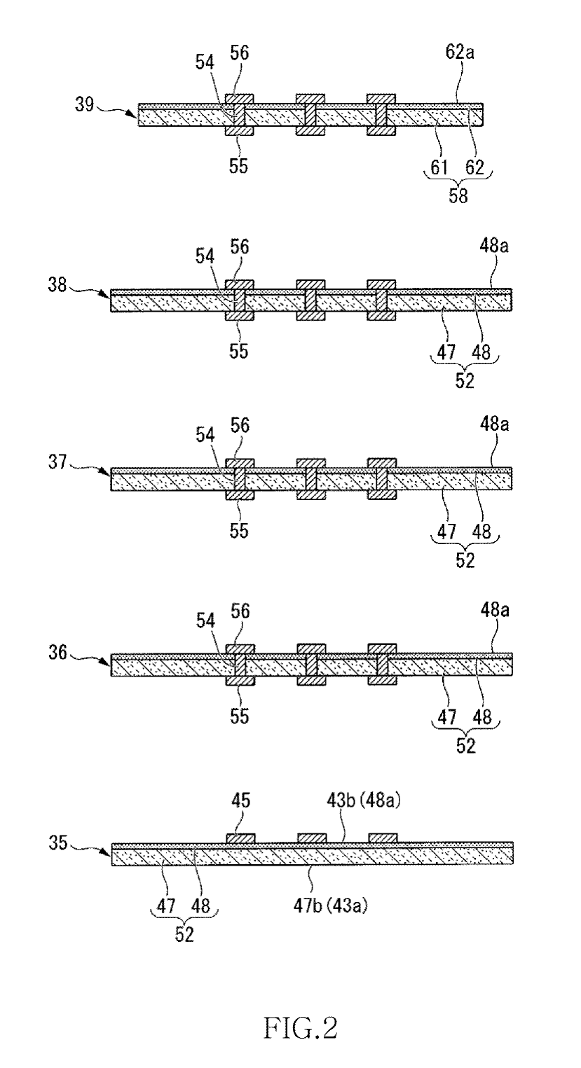

A process of manufacturing the semiconductor device 10 according to the first embodiment of the present invention will be explained with reference to FIGS. 2 to 5, 6A, 6B, 7A, 7B, 8, 9, 10A, 10B, and 11 to 16.

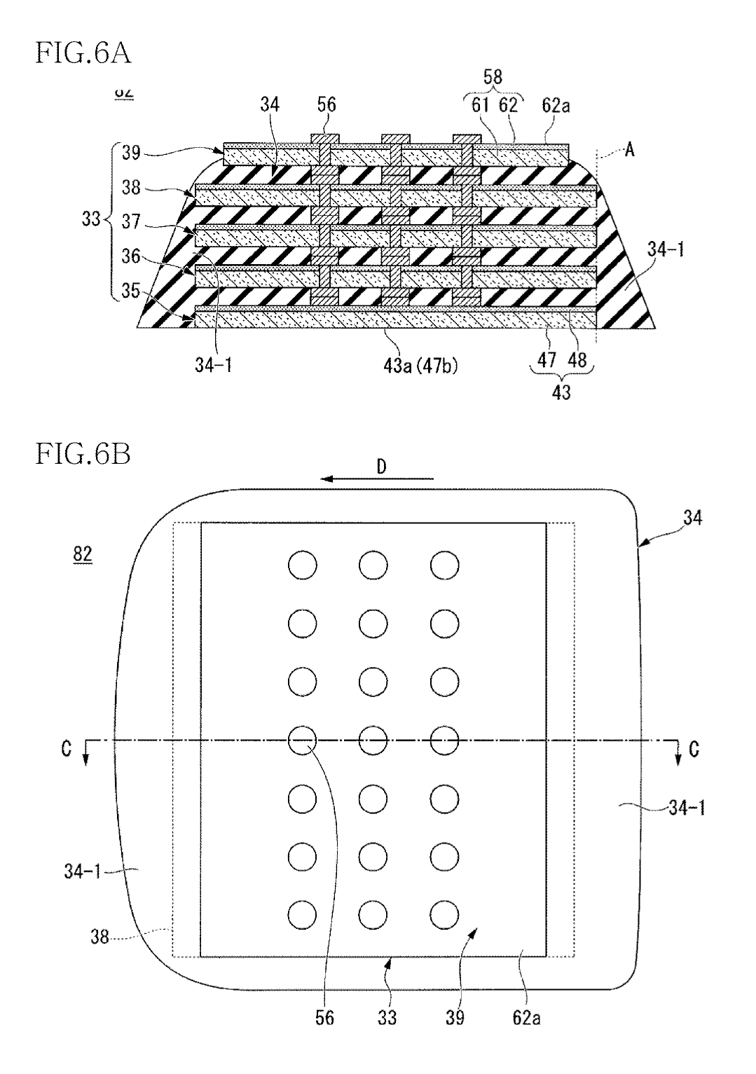

FIGS. 2 to 5, 6A, 8, 9, and 11 to 15 are cross-sectional views of the semiconductor device 10 that is in the process of being produced. FIG. 6B is a plane view of the semiconductor device 10 that is in the process of being produced, which is shown in FIG. 6A.

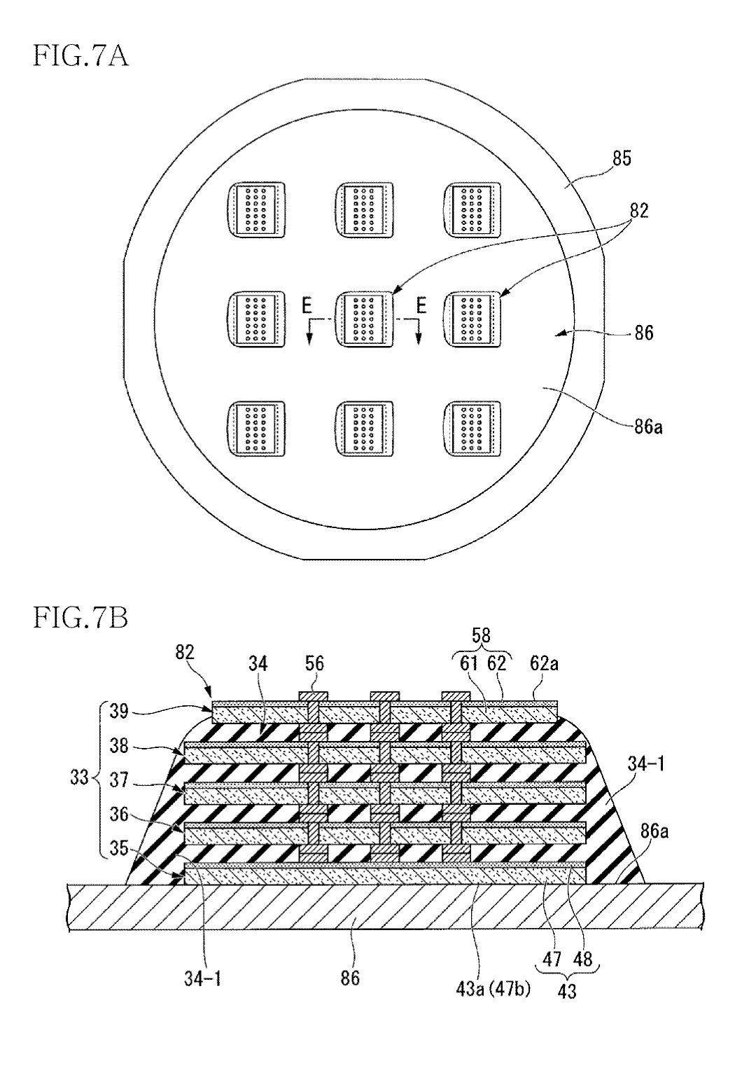

FIG. 7A is a plane view of the semiconductor device 10 that is in the process of being produced. FIG. 7B is a cross-sectional view of the structure shown in FIG. 7A taken along line E-E.

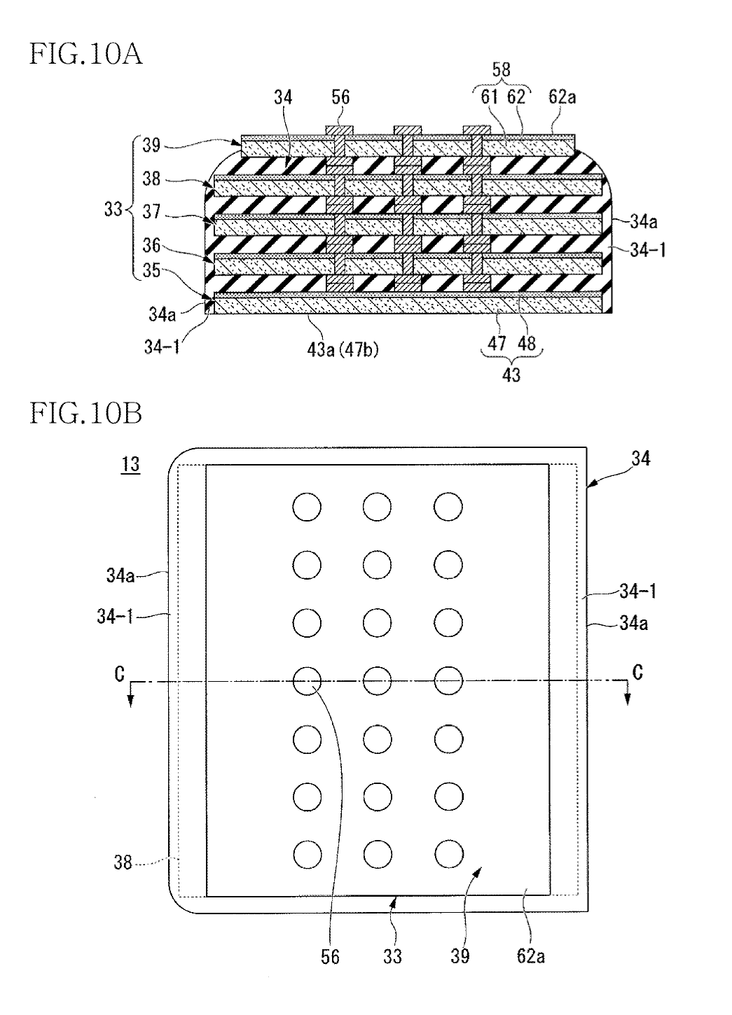

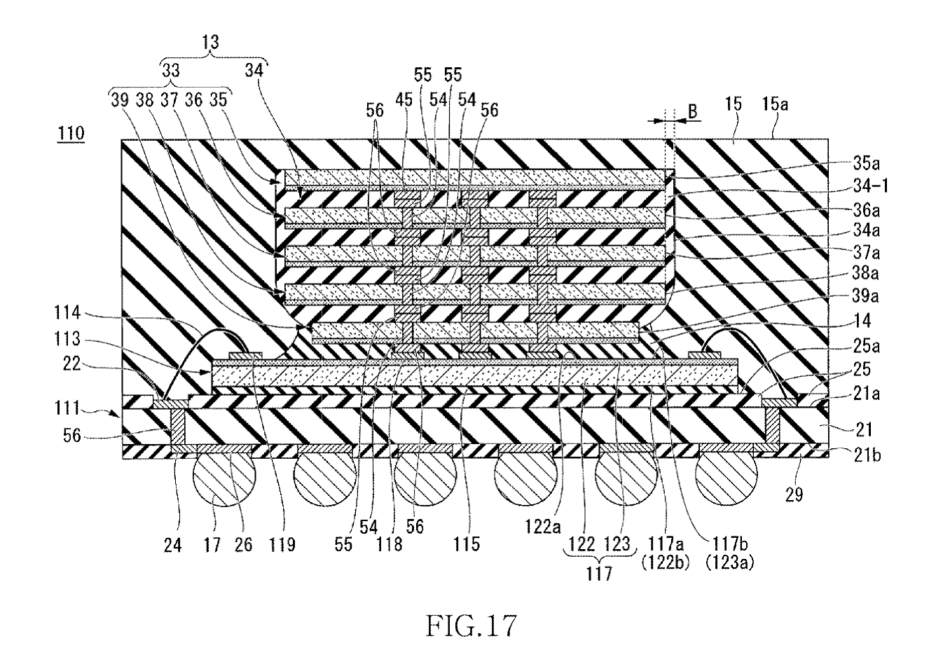

FIG. 10A is a cross-sectional view of the semiconductor device shown in FIG. 10B that is in the process of being produced, taken along line C-C. FIG. 10B is a plane view of the semiconductor device 10 that is in the process of being produced. FIG. 17 is a cross-sectional view of a plurality of semiconductor devices 10 produced.

In FIGS. 2 to 5, 6A, 6B, 7A, 7B, 8, 9, 10A, 10B, and 11 to 16, the same components as those of the semiconductor device 10 of the first embodiment are represented by the same reference symbols.

With reference to FIGS. 2 to 5, 6A, 6B, 7A, 7B, 8, 9, 10A, 10B, and 11 to 16, a method of manufacturing the semiconductor device 10 of the first embodiment will be described.

First, in a process shown in FIG. 2, as a plurality of semiconductor chips, the following chips are prepared: the first semiconductor chip 35 that includes the first chip body 43, whose one surface 43a (the back surface 47b of the semiconductor substrate 47) is a flat plane, and the surface bump electrodes 45, which is disposed on the other surface 43b (the surface 48a of the circuit element layer 48) of the first chip body 43; the second semiconductor chips 36 to 38 that each include the second chip body 52, the penetration electrodes 54, which passes through the second chip body 52, the back-surface bump electrodes 55, which are disposed at one end of the penetration electrodes 54, and the surface bump electrodes 56, which are disposed at the other end of the penetration electrodes 54; and the second semiconductor chip 39 that includes the second chip body 58, the penetration electrodes 54, which passes through the second chip body 58, the back-surface bump electrodes 55, which are disposed at one end of the penetration electrodes 54, and the surface bump electrodes 56, which are disposed at the other end of the penetration electrodes 54.

At this time, for the first and second semiconductor chips 35 to 38, a rectangular semiconductor memory chip for (or more specifically, a DRAM, for example) is used. For the second semiconductor chip 39, a rectangular semiconductor chip for interface function is used.

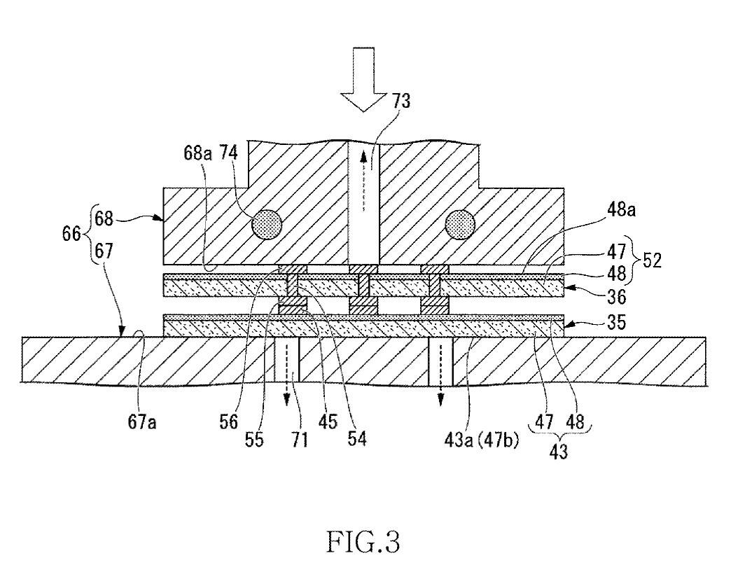

Before a process shown in FIG. 3 is explained, the schematic configuration of a bonding device 66, which is used in the process shown in FIG. 3, will be described.

As shown in FIG. 3, the bonding device 66 includes a stage 67 and a bonding tool 68. The stage 67 includes a substrate mounting surface 67a and a first adsorption hole 71.

The substrate mounting surface 67a is a plane on which a semiconductor chip or a wiring substrate is placed, and is a flat plane.

The first adsorption hole 71 is exposed from the substrate mounting surface 67a, and is designed to pull a substrate, such as a semiconductor chip or wiring substrate, which is placed on the substrate mounting surface 67a.

Incidentally, although not shown in the diagram, the stage 67 includes a heater to heat the substrate pulled toward the substrate mounting surface 67a.

The bonding tool 68 includes an adsorption surface 68a, a second adsorption hole 73, and a heater 74. The adsorption surface 68a is a plane that comes in contact with a semiconductor chip that the bonding tool 68 has pulled. The second adsorption hole 73 is exposed from the adsorption surface 68a, and is designed to pull a semiconductor chip. The heater 74 heats the semiconductor chip that has been pulled.

The following describes the process shown in FIG. 3.

In the process shown in FIG. 3, the first semiconductor chip 35 is pulled onto the stage 67 in such a way that the substrate mounting surface 67a of the stage 67 of the bonding device 66 comes in contact with one surface 43a (the back surface 47b of the semiconductor substrate 47) of the first chip body 43.

Then, the bonding tool 68 is used to pull the second semiconductor chip 36 in such a way that the surface 48a of the circuit element layer 48 faces the adsorption surface 68a. Then, as the bonding tool 68 is moved, the back-surface bump electrodes 55 of the second semiconductor chip 36 and the surface bump electrodes 45 of the first semiconductor chip 35 are so disposed as to face each other.

Then, the first and second semiconductor chips 35 and 36 are heated at a high temperature (about 300 degrees Celsius, for example). After the SnAg solder film, which constitutes the back-surface bump electrodes 55, is melted, the bonding tool 68 is moved downward. As a result, the back-surface bump electrodes 55 come in contact with the surface bump electrodes 45, and a load is applied thereto. In this manner, the thermal compression bonding of the back-surface bump electrodes 55 and the surface bump electrodes 45 is carried out.

As a result, on the first semiconductor chip 35, the second semiconductor chip 36 is flip-chip mounted. Moreover, a gap is formed between the first and second semiconductor chips 35 and 36.

In a process shown in FIG. 4, in a similar way to the process of flip-chip mounting the second semiconductor chip 36 on the first semiconductor chip 35, the thermal compression bonding of the surface bump electrodes 56 of the second semiconductor chip 36 and the back-surface bump electrodes 55 of the second semiconductor chip 37 are carried out. In this manner, on the second semiconductor chip 36, the second semiconductor chip 37 is flip-chip mounted. At this time, a gap is formed between the first and second semiconductor chips 36 and 37.

Next, in a similar way to the process of flip-chip mounting the second semiconductor chip 36 on the first semiconductor chip 35, the thermal compression bonding of the surface bump electrodes 56 of the second semiconductor chip 37 and the back-surface bump electrodes 55 of the second semiconductor chip 38 are carried out. In this manner, on the second semiconductor chip 37, the second semiconductor chip 38 is flip-chip mounted. At this time, a gap is formed between the first and second semiconductor chips 37 and 38.

Next, in a similar way to the process of flip-chip mounting the second semiconductor chip 36 on the first semiconductor chip 35, the thermal compression bonding of the surface bump electrodes 56 of the second semiconductor chip 38 and the back-surface bump electrodes 55 of the second semiconductor chip 39 are carried out. In this manner, on the second semiconductor chip 38, the second semiconductor chip 39 is flip-chip mounted. At this time, a gap is formed between the first and second semiconductor chips 38 and 39.

In that manner, through the penetration electrodes 54, the back-surface bump electrodes 55, and the surface bump electrodes 56, on the first semiconductor chip 35, the second semiconductor chips 36 to 39 are stacked and mounted. Thus, the chip laminated body 33, which is made up of the first and second semiconductor chips 35 to 39 stacked and mounted, is formed.

When the second semiconductor chips 36 to 39 are mounted on the first semiconductor chip 35, the side surfaces 35a, 36a, 37a, and 38a of the first and second semiconductor chips 35 to 38, the outer shapes of which are equal in size, are so disposed as to be flush with the plane A, which is perpendicular to the substrate mounting surface 67a of the stage 67.

Incidentally, when the second semiconductor chips 35 to 39 are flip-chip mounted, ultrasonic waves may also be applied along with the load.

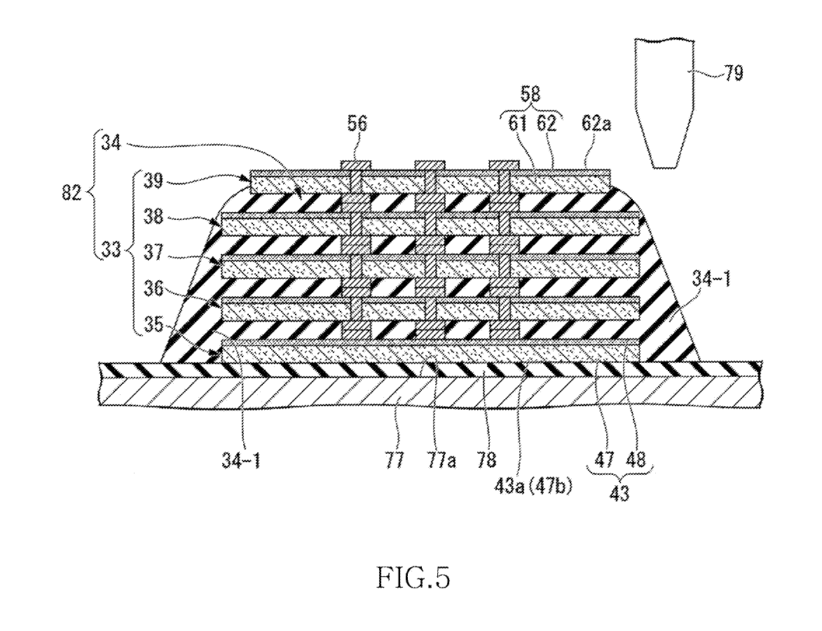

In a process shown in FIG. 5, the underfill material 34 (e.g. thermosetting resin), which fills the gaps between the first and second semiconductor chips 35 to 39 that make up the chip laminated body 33, is formed in such a way that the fillet portion 34-1 is formed around the chip laminated body 33.

In this manner, a structure 82 that contains the chip laminated body 33 and the underfill material 34 having the fillet portion 34-1 (i.e. the chip laminated body 13 with the underfill material whose fillet portion 34-1 is not trimmed yet) is formed.

More specifically, when thermosetting resin is used for the underfill material 34, the underfill material 34 is formed in the following manner.

First, the chip laminated body 33 is so disposed that a sheet material 78 attached to the flat surface 77a of the stage 77 comes in contact with one surface 43a of the first chip body 43.

Then, through a dispenser 79, drops of liquid underfill material 34 are placed onto one of the four side walls of the chip laminated body 33. Therefore, the gaps between the first and second semiconductor chips 35 to 39 are sealed by capillary phenomenon.

At this time, in the situation shown in FIG. 5, the upper surface 62a of the circuit element layer 62 of the second semiconductor chip 39, which is disposed on the top layer, and the surface bump electrodes 56 are exposed from the liquid underfill material 34.

Moreover, because the chip laminated body 33 is so disposed that the sheet material 78 is in contact with one surface 43a (the back surface 47b of the semiconductor substrate 47) of the first chip body 43, the underfill material 34 is not formed on the back surface 47b of the semiconductor substrate 47.

Then, the liquid underfill resin 34 is solidified at a predetermined temperature (e.g. 140 degrees Celsius). As a result, the underfill material 34 having the fillet portion 34-1 is formed.

In a process shown in FIGS. 6A and 6B, the structure 82 having the fillet portion 34-1, shown in FIG. 5, is picked up from the sheet member 78.

At this stage, as shown in FIG. 6A, on the four side walls around the chip laminated body 33, the fillet portion 34-1 that is not trimmed is formed.

Moreover, in the process shown in FIG. 5, drops of the liquid underfill resin 34 are placed from one side (side wall) that is positioned on the right side of the chip laminated body 33 shown in FIG. 6A. Therefore, the liquid underfill resin 34 flows in the “D” direction as shown in FIG. 6B.

Accordingly, the fillet portion 34-1 formed on the right side of the chip laminated body 33 shown in FIG. 6A is wider than the fillet portion 34-1 formed on the left side of the chip laminated body 33.

Incidentally, as the processes illustrated in FIGS. 1 to 5, 6A, and 6B are carried out, a plurality of structures 82 are formed.

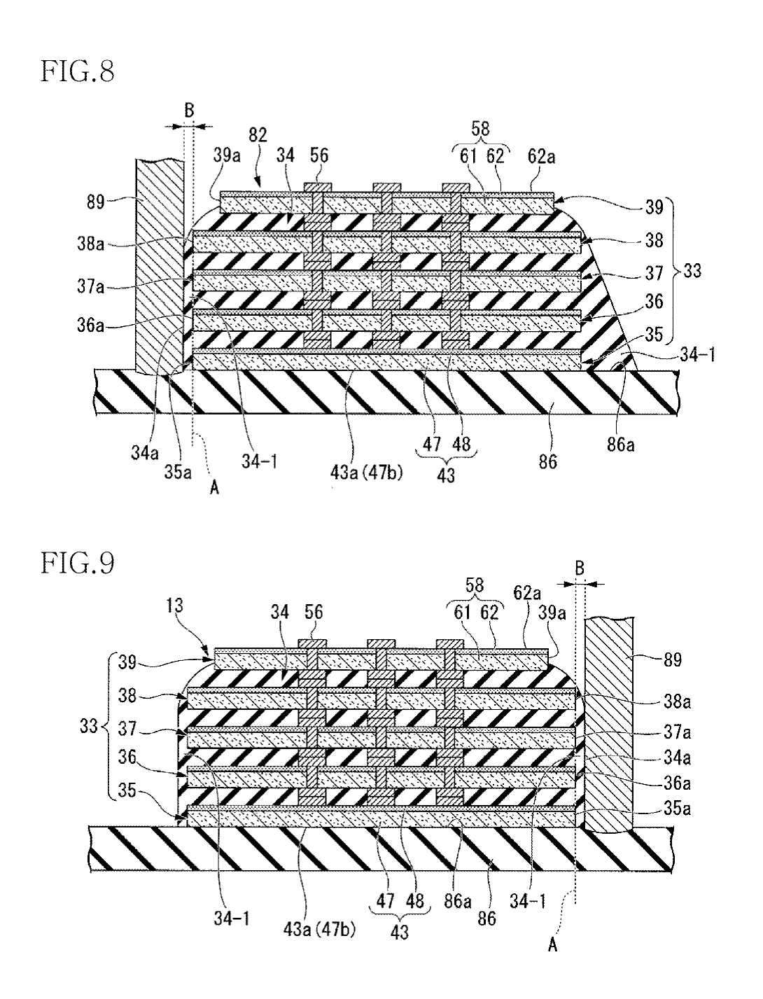

In a process shown in FIGS. 7A and 7B, a dicing tape 86 is attached to the inside of a ring-shaped jig 85. On an upper surface 86a of the dicing tape 86, a plurality of structures 82 are attached at predetermined intervals (or more specifically, at intervals that make it possible to appropriately carry out the trimming of the fillet portion 34-1 with the use of a dicing blade 89 in a process described later with reference to FIGS. 8 and 9).

At this time, a plurality of structures 82 are attached to the upper surface 86a of the dicing tape 86 in such a way that the upper surface 86a of the dicing tape 86 comes in contact with one surface 43a (the back surface 47b of the semiconductor substrate 47) of the first chip body 43.

In a process shown in FIG. 8, the dicing blade 89 is used to trim one of the four fillet portions 34-1 that are formed on the four side walls of the chip laminated body 33. As a result, a plane 34a is formed: the plane 34a is disposed near the side surfaces 35a, 36a, 37a, and 38a of the first and second semiconductor chips 35 to 38, and runs parallel to the side surfaces 35a, 36a, 37a, 38a, and 39a of the first and second semiconductor chips 35 to 39.

At this time, the distance B from the side surfaces 35a, 36a, 37a, and 38a (i.e. the plane A) of the first and second semiconductor chips 35 to 38 to the plane 34a of the underfill material 34 may be 50 μm, for example.

In a process shown in FIG. 9, in the same way as the process shown in FIG. 8, the remaining three fillet portions 34-1, which are not trimmed yet, are sequentially trimmed, thereby forming three planes 34a.

In that manner, the chip laminated body 13 with the underfill material is so formed as to include the chip laminated body 33, which is made up of the first and second semiconductor chips 35 to 39 stacked and mounted; and the underfill material 34, which seals the gaps between and the first and second semiconductor chips 35 to 39 and has the planes 34a for the four trimmed fillet portions 34-1.

In that manner, the fillet portions 34-1, which are formed on the four side walls of the chip laminated body 33, are trimmed to form the planes 34a, which run parallel to the side surfaces 35a, 36a, 37a, and 38a of the first and second semiconductor chips 35 to 38. As a result, it is possible to curb variation in the external dimensions of the chip laminated body 13 with the underfill material.

Therefore, it becomes possible to manage the external dimensions of the chip laminated body 13 with the underfill material.

As the external dimensions of the chip laminated body 13 with the underfill material become stable, the resistance of the chip laminated body 13 with the underfill material can be improved against the stress resulting from an external force at the time of handling.

Furthermore, the fillet portion 34-1 is trimmed. Therefore, it is possible to reduce the stress of the underfill material 34 at a time when the chip laminated body 13 with the underfill material is heated.

Therefore, it is possible to prevent the breakage (chip cracking) of the first and second semiconductor chips 35 to 39 that are made thin (e.g. semiconductor chips with a thickness of 50 μm or less, for example), and the breaking of the connection portions (joint areas) between the first and second semiconductor chips 35 to 39.

Since the fillet portion 34-1 is trimmed, the chip laminated body 13 with the underfill material can be made smaller in size. As a result, the wiring substrate 11 on which the chip laminated body 13 with the underfill material is mounted can be made smaller in size.

Furthermore, as the wiring substrate 11 becomes smaller in size, the semiconductor device 10 (See FIG. 1) having the wiring substrate 11 and the chip laminated body 13 with the underfill material can also be smaller in size.

Incidentally, in the processes shown in FIGS. 8 and 9, as an example of trimming the fillet portions 34-1 through a cutting operation, an example of using a dicing device (dicing blade 89) has been described. However, cutting devices other than the dicing device may be used in trimming the fillet portions 34-1.

A polishing device may be used to polish and trim the fillet portions 34-1. A cutting operation and a polishing operation may be used in combination to trim the fillet portions 34-1.

In a process shown in FIGS. 10A and 10B, the chip laminated body 13 with the underfill material, on which the four planes 34a shown in FIG. 9 have been formed, is picked up from the dicing tape 86.

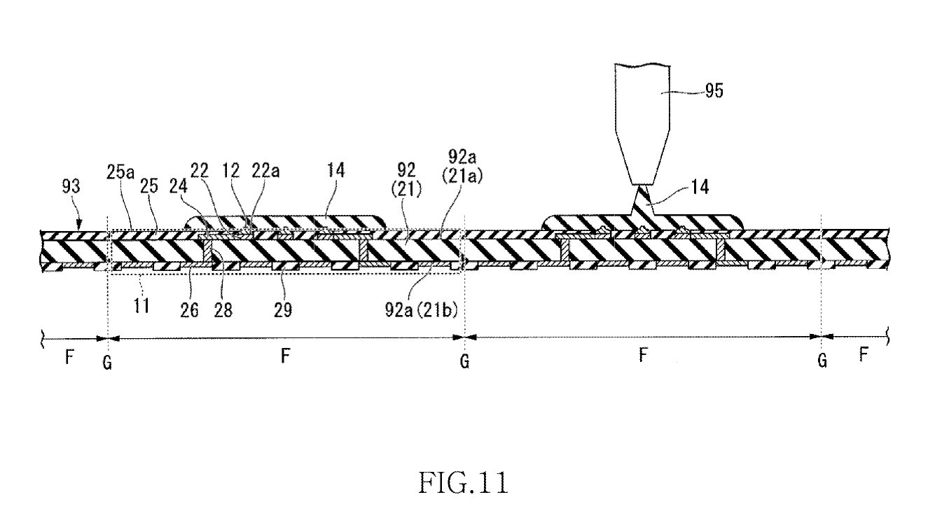

In a process shown in FIG. 11, an insulating substrate 92 having a plurality of wiring substrate formation areas F and dicing lines G is prepared: the dicing lines G mark off a plurality of wiring substrate formation areas F.

Then, a well-known method is used to form the connection pads 22, the wirings 24, the first solder resist 25, the external connection pads 26, the penetration electrodes 28, and the second solder resist 29 on the insulating substrate 92.

As a result, a wiring mother substrate 93 on which wiring substrates 11 are formed in a plurality of the wiring substrate formation areas F is formed. At this stage, a plurality of the wiring substrates 11 are still connected, not divided into individual pieces.

Then, on the bump mounting surface 22a of the connection pads 22, an Au bump is formed as the wire bumps 12.

More specifically, the tip of an Au wire is melted by discharge of electricity, forming a ball. Ultrasonic waves are then used to bond the ball to the bump mounting surface 22a of the connection pads 22. Then, the Au wire is cut. In this manner, the ball is formed. Incidentally, leveling may be carried out when necessary so that the height of the Au bump becomes uniform.

Then, onto the upper surface 25a of the first solder resist 25 that corresponds to a mounting area for the chip laminated body 13 with the underfill material, the liquid first sealing resin 14 (e.g. NCP (Non-Conductive Paste)) is supplied through a dispenser 95.

As a result, a plurality of connection pads 22 and wire bumps 12 that are formed on the wiring substrate 11 are covered with the liquid first sealing resin 14.

The liquid first sealing resin 14 are formed on all the wiring substrates 11 that make up the wiring mother substrate 93.

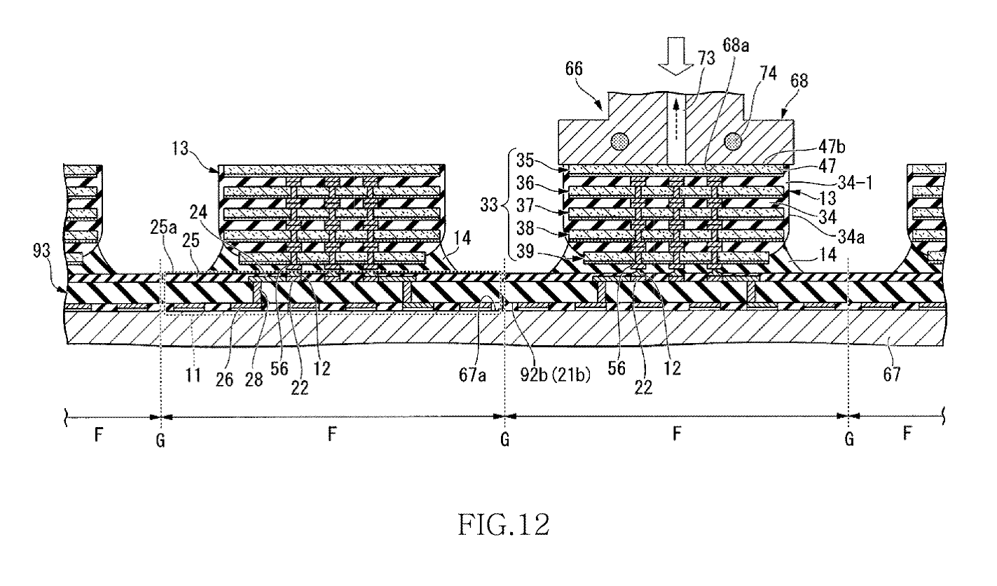

Then, in a process shown in FIG. 12, the wiring mother substrate 93, on which the wire bumps 12 and the liquid first sealing resin 14 are formed, is placed on the substrate mounting surface 67a of the stage 67. At this time, the wiring mother substrate 93 is so placed that the back surface 92b of the insulating substrate 92 faces the substrate mounting surface 67a of the stage 67.

Then, the bonding tool 68 is used to pull the back surface 47b of the semiconductor substrate 47, which constitutes the chip laminated body 13 with the underfill material shown in FIG. 10A. In this manner, the chip laminated body 13 with the underfill material is picked up.

Then, the bonding tool 68 is moved, and the wire bumps 12 and the surface bump electrodes 56 of the chip laminated body 13 with the underfill material are so disposed as to face each other.

Subsequently, the bonding tool 68 is used to heat the chip laminated body 13 with the underfill material at a high temperature (e.g. 300 degrees Celsius), while a load is applied to the chip laminated body 13 with the underfill material. In this manner, the chip laminated body 13 with the underfill material is pushed onto the liquid first sealing resin 14.

In this manner, the thermal compression bonding of the surface bump electrodes 56 and the wire bumps 12 is carried out. Accordingly, on the wiring substrate 11, the chip laminated body 13 with the underfill material is flip-chip mounted. Moreover, the gap between the wiring substrate 11 and the chip laminated body 13 with the underfill material is sealed by the first sealing resin 14 cured.

Incidentally, in the process shown in FIG. 12, on all the wiring substrates 11 that make up the wiring mother substrate 93, the chip laminated bodies 13 with the underfill material are flip-chip mounted.

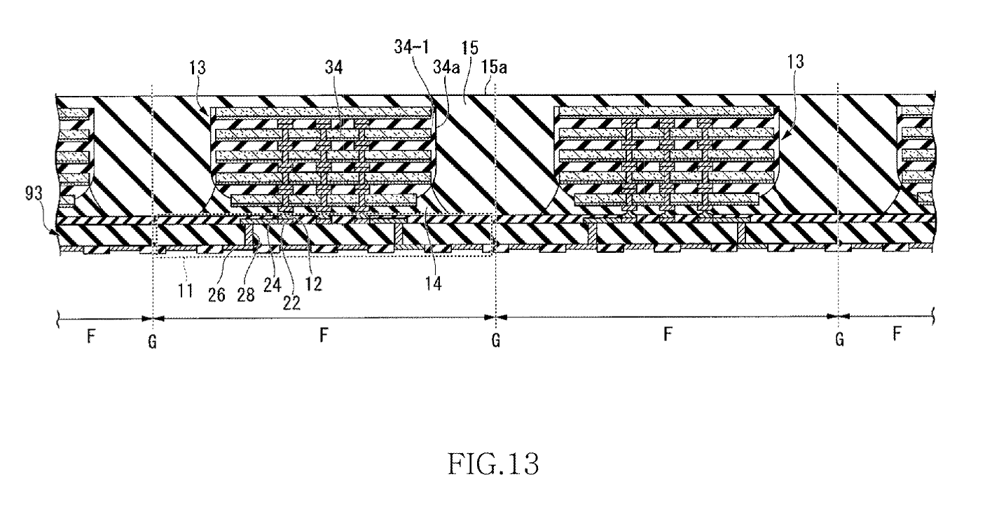

In a process shown in FIG. 13, from the bonding device 66 shown in FIG. 12, the wiring mother substrate 93 on which a plurality of the chip laminated bodies 13 with the underfill material and the first sealing resin 14 are formed is taken out.

Then, on the upper surface 25a of the first solder resist that constitutes the wiring mother substrate 93, a plurality of the chip laminated bodies 13 with the underfill material and the first sealing resin 14 are sealed. Moreover, the second sealing resin 15 whose upper surface 15a is a flat plane is formed.

For the second sealing resin 15, for example, mold resin may be used. In this case, the second sealing resin 15 may be formed by transfer mold method, for example.

If the transfer mold method is used, in a space formed between an upper mold and a lower mold, the structure shown in FIG. 12 (except the bonding device 66) is placed. Then, the heated and melted resin (or the base material for the second sealing resin 15) is injected into the space.

Subsequently, the melted resin is heated (or cured) at a predetermined temperature (e.g. about 180 degrees Celsius). Then, the resin is baked at a predetermined temperature. In this manner, the mold resin is completely cured. As a result, the second sealing resin 15 is formed. The resin that serves as the base material for the second sealing resin 15 may be thermosetting resin such as epoxy resin, for example.

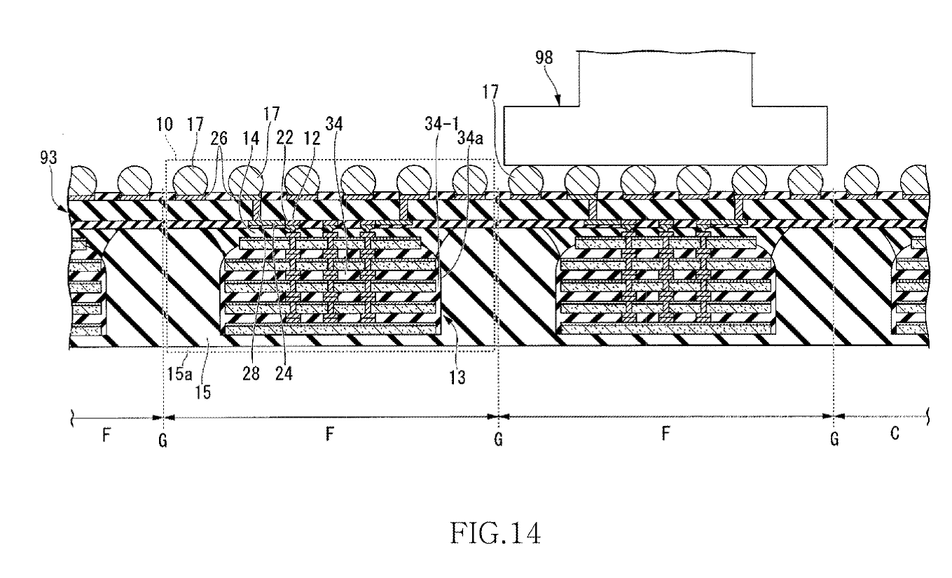

In a process shown in FIG. 14, the structure shown in FIG. 13 is flipped upside-down. Then, on a plurality of external connection pads 26 that are formed on a plurality of the wiring substrates 11 (i.e. the wiring mother substrate 93), external connection terminals 17 are formed. For the external connection terminals 17, for example, solder balls may be used.

If the solder balls are used for the external connection terminals 17, the method described below is used to form the external connection terminals 17 on a plurality of external connection pads 26.

First, a mounting tool 98 of a ball mounter is used to pull and keep a plurality of solder balls, while transferring and forming a flux onto a plurality of solder balls.

Then, on a plurality of the external connection pads 26 that are formed on the wiring mother substrate 93, the solder balls are placed. After that, heat treatment (reflow treatment) is applied to the wiring mother substrate 93 on which the solder balls are formed. In this manner, the solder balls, which serve as the external connection terminals 17, are formed on the external connection pads 26.

As a result, a plurality of semiconductor devices 10 are formed: the semiconductor devices 10 include the wiring substrates 11, the chip laminated bodies 13 with the underfill material, the first sealing resin 14, the second sealing resin 15, and the external connection terminals 17, and are connected together.

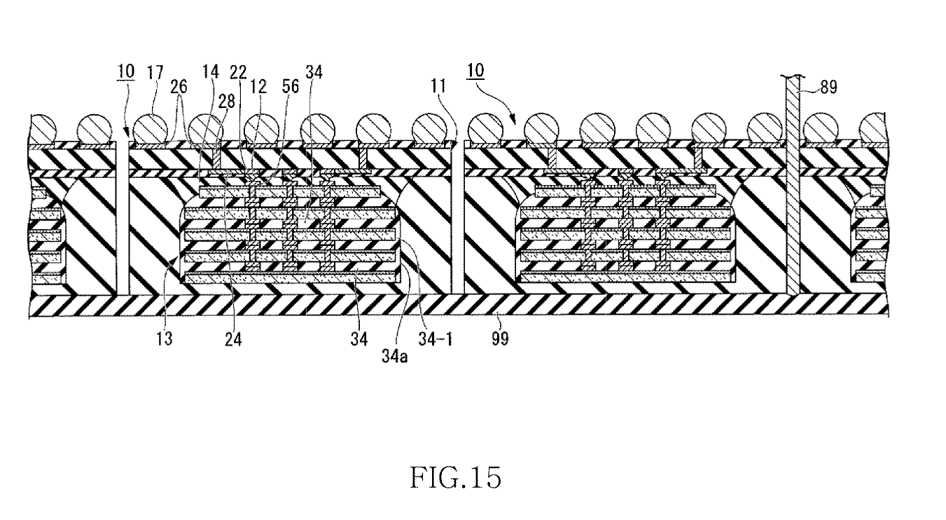

In a process shown in FIG. 15, on the upper surface 15a of the second sealing resin 15 that makes up the structure shown in FIG. 14 (except the mounting tool 98), a dicing tape 99 is attached.

Then, the dicing blade 89 is used to cut the structure shown in FIG. 14 along the dicing lines G. As a result, a plurality of semiconductor devices 10 are turned into individual pieces. At this time, a plurality of wiring substrates 11, too, are turned into individual pieces.

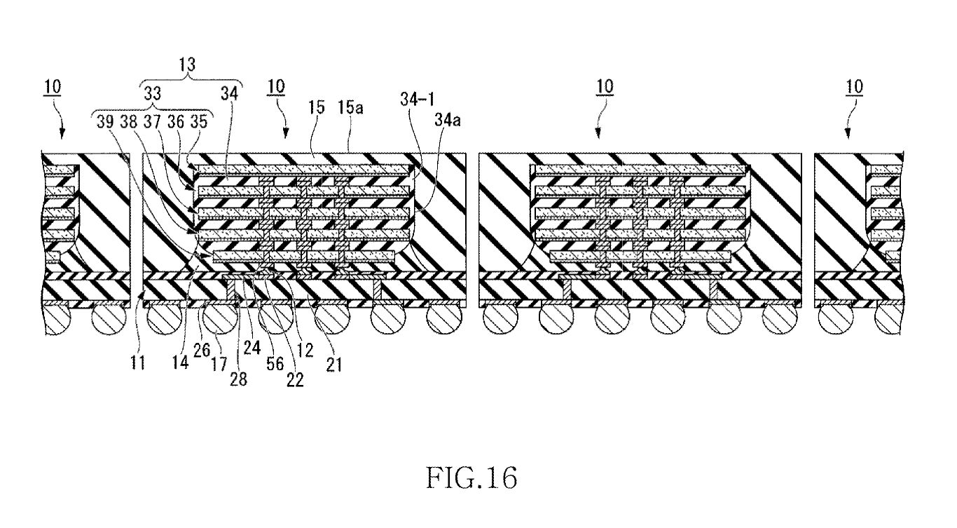

In a process shown in FIG. 16, the structure shown in FIG. 15 (except the dicing blade 89) is flipped upside-down. Then, the dicing tape 99 is separated from the structure shown in FIG. 15. In this manner, a plurality of CoC-type semiconductor devices 10 are produced.

According to the manufacturing method of the semiconductor device of the first embodiment, as the first and second semiconductor chips 35 to 39 are stacked and mounted through the penetration electrodes 54, the chip laminated body 33 that is made up of the first and second semiconductor chips 35 to 39 stacked is formed. Then, the underfill material 34 that fills the gaps between the first and second semiconductor chips 35 to 39 is so formed that the fillet portions 34-1 are formed around the chip laminated body 33. Then, the fillet portions 34-1 formed around the chip laminated body 33 are trimmed to form the chip laminated body 13 with the underfill material, which is made up of the chip laminated body 33 and the underfill material 34. Therefore, it is possible to curb variation in the shape of the fillet portions 34-1. Thus, it is possible to curb variation in the outer shape of the chip laminated body 13 with the underfill material, which can occur due to variation in the shape of the fillet portions 34-1.

Therefore, it becomes possible to manage the external dimensions of the chip laminated body 13 with the underfill material.

As the external dimensions of the chip laminated body 13 with the underfill material become stable, the resistance of the chip laminated body 13 with the underfill material can be improved against the stress resulting from an external force at the time of handling.

Furthermore, the fillet portion 34-1 is trimmed. Therefore, it is possible to reduce the stress of the underfill material 34 at a time when the chip laminated body 13 with the underfill material is heated.

Therefore, it is possible to prevent the breakage (chip cracking) of the first and second semiconductor chips 35 to that are made thin (e.g. semiconductor chips with a thickness of 50 μm or less, for example), and the breaking of the connection portions (joint areas) between the first and second semiconductor chips 35 to 39.

Since the fillet portion 34-1 is trimmed, the chip laminated body 13 with the underfill material can be made smaller in size. As a result, the wiring substrate 11 on which the chip laminated body 13 with the underfill material is mounted can be made smaller in size.

Furthermore, as the wiring substrate 11 becomes smaller in size, the semiconductor device 10 (See FIG. 1) having the wiring substrate 11 and the chip laminated body 13 with the underfill material can also be smaller in size.

### Second Embodiment

A semiconductor device according to a second embodiment of the present invention will be explained with reference to FIG. 17. In FIG. 17, the same components as those of the semiconductor device 10 of the first embodiment are represented by the same reference symbols.

As shown in FIG. 17, the semiconductor device 110 of the second embodiment has the same configuration as the semiconductor device 10 except that: instead of the wiring substrate 11 that is provided in the semiconductor device 10 of the first embodiment, a wiring substrate 111 is provided; and that a logic semiconductor chip 113, a plurality of metal wires 114, and an adhesive 115 are provided.

The wiring substrate 111 has the same configuration as the wiring substrate 11 described in the first embodiment except that: the connection pads 22 are disposed at the outer periphery of the surface 21a of the wiring substrate body 21; the wirings 24 are disposed on the back surface 21b of the wiring substrate body 21; the connection pads 22 and the wirings 24 and the penetration electrodes 56 are connected; and the wirings 24 and the external connection pads 26 are connected.

The logic semiconductor chip 113 includes a third chip body 117, which has one flat surface 117a and the other surface 117b; a plurality of surface bump electrodes 118 (third bump electrode); and a plurality of surface bump electrodes 119 (fourth bump electrode).

The logic semiconductor chip 113 is bonded to the first solder resist 25 of the wiring substrate 111 with the adhesive 115, which is provided on one surface 117a of the third chip body 117.

The third chip body 117 is in the shape of a rectangle, and includes a semiconductor substrate 122 and a circuit element layer 123.

For the semiconductor substrate 122, for example, a single-crystal silicon substrate may be used. The semiconductor substrate 122 has a surface 122a, which is a flat plane, and a back surface 122b.

The circuit element layer 123 is formed on the surface 122a of the semiconductor substrate 122. The circuit element layer 123 includes transistors, which are not shown in the diagram, a plurality of interlayer insulating films stacked, and wiring patterns (vias and wiring), which are formed on the plurality of the interlayer insulating films. On the circuit element layer 123, a logic element (not shown) is formed.

The surface bump electrodes 118 are provided on the surface 123a of the circuit element layer 123 (or on the other surface 117b of the third chip body 117). The surface bump electrodes 118 are disposed in a central portion of the surface 123a of the circuit element layer 123 (i.e. in amounting area of the chip laminated body 13 with the underfill material).

The surface bump electrodes 118 are connected to the surface bump electrodes 56 of the chip laminated body 13 with the underfill material. That is, the chip laminated body 13 with the underfill material is flip-chip mounted on the logic semiconductor chip 113, which is bonded onto the wiring substrate 111.

The surface bump electrodes 119 are provided on the surface 123a of the circuit element layer 123. The surface bump electrodes 119 are disposed at the outer periphery of the surface 123a of the circuit element layer 123.

The surface bump electrodes 119 are connected to the other end of the metal wires 114, one end of which is connected to the connection pads 22 of the wiring substrate 111.

That is, the logic semiconductor chip 113 is connected by wire bonding to the wiring substrate 111. Accordingly, the logic semiconductor chip 113 is electrically connected to the wiring substrate 111, and electrically connects the chip laminated body 33 and the wiring substrate 111.

For the surface bump electrodes 118 and 119, for example, a Cu/Ni/Au laminated film may be used: the Cu/Ni/Au laminated film is made by sequentially stacking a Cu film, a Ni film, and an Au film on the surface 123a of the circuit element layer 123. The Cu/Ni/Au laminated film may be made by plating.

The first sealing resin 14 is so disposed as to fill the gap between the logic semiconductor chip 113 and the chip laminated body 13 with the underfill material.

The second sealing resin 15 is provided on the upper surface 25a (or the principal surface of the wiring substrate 111) of the first solder resist 25 in such a way as to seal the chip laminated body 13 with the underfill material, the first sealing resin 14, the logic semiconductor chip 113, and the metal wires 114.

The semiconductor device of the second embodiment can achieve the same advantageous effects as the semiconductor device 10 of the first embodiment. Moreover, since the semiconductor device of the second embodiment includes the memory semiconductor chips stacked (the first and second semiconductor chips 35 to 38) and the logic semiconductor chip 113, the semiconductor device 110 can have a higher level of functionality.

Incidentally, what is described in the second embodiment is an example in which the logic semiconductor chip 113 and the wiring substrate 111 are connected by wire bonding, as shown in FIG. 17. However, the following configuration is also available: instead of the surface bump electrodes 119 of the logic semiconductor chip 113, the penetration electrodes 54 and back-surface bump electrodes 55 shown in FIG. 17 are provided; through the penetration electrodes 54, the logic semiconductor chip 113 and the wiring substrate 111 may be electrically connected.

The semiconductor device 110 of the second embodiment can be produced by the method described below.

First, the following components are prepared: the logic semiconductor chip 113, whose one surface 117a is a flat surface and which has the surface bump electrodes 118 and 119 on the other surface 117b; and the chip laminated body 13 with the underfill material shown in FIGS. 10A and 10B, which is formed by performing the same processes as those shown in FIGS. 2 to 5, 6A, 6B, 7A, 7B, 8, 9, 10A, and 10B, which are described in the first embodiment.

Then, the logic semiconductor chip 113 is bonded in such a way that one surface (the back surface 122b of the semiconductor substrate 122) of the logic semiconductor chip 113 faces the principal surface (the upper surface 25a of the first solder resist 25) of the wiring substrate 111 on which the connection pads 22 is provided.

Then, onto the surface bump electrodes 118, the chip laminated body 13 with the underfill material is flip-chip mounted. Moreover, the first sealing resin 14 is formed to seal the gap between the chip laminated body 13 with the underfill material and the logic semiconductor chip 113. Subsequently, the surface bump electrodes 119 and the connection pads 22 are connected by wire bonding.

Then, on the principal surface of the wiring substrate 111, the second sealing resin 15 is formed to seal the chip laminated body 13 with the underfill material, the first sealing resin 14, and the logic semiconductor chip 113.

Subsequently, on the surface (the back surface 21b of the wiring substrate body 21) of the wiring substrate 111 that is opposite to the principal surface, the external connection pads 26, which is electrically connected to the connection pads 22, is formed.

After that, the same processes as those shown in FIGS. 15 and 16, which are described in the first embodiment, are carried out. As a result, a plurality of semiconductor devices 110 of the second embodiment are produced.

The manufacturing method of the semiconductor device of the second embodiment can achieve the same advantageous effects as the manufacturing method of the semiconductor device 10 of the first embodiment. Moreover, since the semiconductor device of the second embodiment includes the memory semiconductor chips stacked (the first and second semiconductor chips 35 to 38) and the logic semiconductor chip 113, the semiconductor device 110 can have a higher level of functionality.

### Third Embodiment

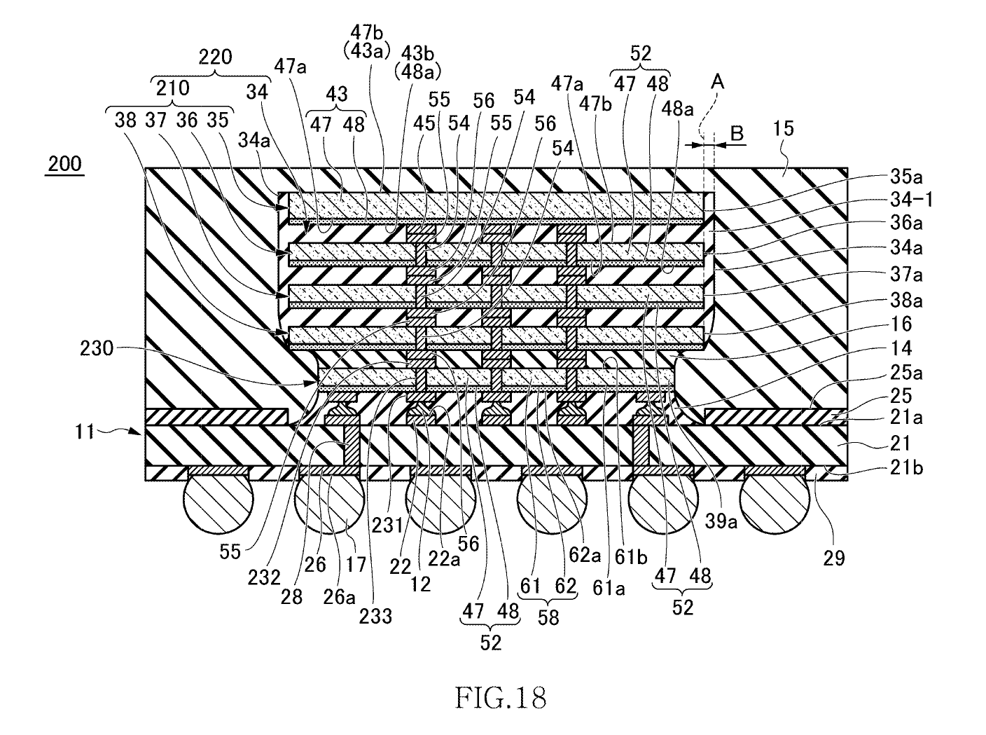

A semiconductor device according to a third embodiment of the present invention will be explained with reference to FIG. 18. In FIG. 18, the same components as those of the semiconductor device 10 of the first embodiment are represented by the same reference symbols.

As shown in FIG. 18, the semiconductor device 200 of the present embodiment is different from the semiconductor device 100 of the first embodiment shown in FIG. 1 mainly in that: the chip laminated body 13 with the underfill material shown in FIG. 1 is replaced with a chip laminated body 220 with an underfill material; and the second semiconductor chip 39 is replaced with a third semiconductor chip 230.

The chip laminated body 220 with the underfill material includes a chip laminated body 210 and an underfill material 34.

The chip laminated body 210 is made up of the first semiconductor chip 35 and a plurality of second semiconductor chips 36 to 38. Similarly to the first embodiment, for the semiconductor chips 35 to 38, a semiconductor chip for memory, such as a DRAM, may be used. Incidentally, the third semiconductor chip 230 is a different component from the chip laminated body 210.

The third semiconductor chip 230 is a logic chip that controls the semiconductor chips 35 to 38. The third semiconductor chip 230, which serves as a logic chip, includes a plurality of surface bump electrodes 231, which are formed on the principal surface, and a plurality of back-surface bump electrodes 232, which are formed on the back surface. The back-surface bump electrodes 232 are electrically connected to the corresponding penetration electrodes 233. The penetration electrodes 233 and the surface bump electrodes 231 are connected to an internal circuit of the third semiconductor chip 230, which is not shown in the diagram. The third semiconductor chip 230 is flip-chip mounted on the wiring substrate 11 in such a way that the surface bump electrodes 231 are connected to the wire bumps 22 provided on the wiring substrate 11.

The space between the wiring substrate 11 and the third semiconductor chip 230 is filled with the first sealing resin 14.

According to the present embodiment, on the third semiconductor chip 230, the chip laminated body 220 with the underfill material is mounted. The space between the third semiconductor chip 230 and the chip laminated body 220 with the underfill material is filled with a third sealing resin 16. For the third sealing resin 16, for example, NCP (Non-Conductive Paste) may be used.

The semiconductor chips 35 to 38 that make up the chip laminated body 210 are electrically connected together via the penetration electrodes 56. In the chip laminated body 210, the underfill material 34 is so provided as to expose a surface of the semiconductor chip 38, which is positioned at a bottom layer (or at a top layer during the process) as shown in FIG. 18, as well as to fill the gaps between the semiconductor chips 35 to 38. Similarly to the first embodiment, on the underfill material 34, the planes 34a that run parallel to the side surfaces of the semiconductor chips 35 to 38 are formed. The outer shape of the chip laminated body 210 are formed by the planes 34a. As shown in FIG. 18, the chip laminated body 210 is stacked and mounted on the third semiconductor chip 230 in such a way that the surface bump electrodes 56 of the semiconductor chip 38, which is positioned at a bottom layer (or at a top layer during the process), is connected to the corresponding back-surface bump electrode 232 of the third semiconductor chip 230, which is a logic chip.

Incidentally, in FIG. 18, the semiconductor chip 35, which is positioned at a top layer (or at a bottom layer during the process), is a memory chip that has the same function as the other semiconductor chips 36 to 38. However, on the semiconductor chip 35, the penetration electrode and the back-surface bump electrode are not formed. The semiconductor chip 35 is made thicker than the other semiconductor chips 36 to 38. For example, the semiconductor chip 35 is so formed as to have a thickness of 100 μm; the other semiconductor chips 36 to 38 are so formed as to have a thickness of 50 μm. The semiconductor chip 35 is a memory chip that is disposed most remote from the third semiconductor chip 230, which is a logic chip.

Incidentally, on the chip laminated body 210 on which the penetration electrodes 56 are disposed linearly in the stacking direction, stress is generated by changes in temperatures during the manufacturing processes and the like as the penetration electrodes 56 swells and contracts. The maximum stress thereof may be applied to a portion of the penetration electrode of the semiconductor chip 35 that is disposed most remote from the wiring substrate 11. There is concern that a chip crack could occur. However, according to the present embodiment, on the semiconductor chip 35 that is disposed most remote from the wiring substrate 11, the penetration electrode and the back-surface bump are not provided. Therefore, the surface of the semiconductor ship 35 on which no penetration electrode is provided is able to withstand the stress. Therefore, the occurrence of a chip crack that can easily occur on the semiconductor chip 35 that is disposed most remote from the wiring substrate 11 is curbed. Thus, it is possible to improve the reliability of the semiconductor device 200.

According to the present embodiment, similarly to the first embodiment, the underfill material 34 is so provided as to fill the gaps between the semiconductor chips 35 to 38 of the chip laminated body 210 and to have the planes 34a, which run parallel to the side faces 35a to 38a of the semiconductor chips 35 to 38, around the chip laminated body 210. Therefore, the stress applied to the chip laminated body 210 can be reduced. Moreover, it is possible to reduce a space occupied by the chip laminated body 220 with the underfill material on the wiring substrate 11. Therefore, the wiring substrate 11 and the semiconductor device 200 can be made smaller in size.

Furthermore, a plurality of the memory chips and the logic chip are stacked in one package. The semiconductor device 200 can be made smaller in horizontal size, and a higher level of functionality can be achieved. Unlike the second embodiment, the logic chip is flip-chip connected to the wiring substrate 11. Therefore, it is also possible to increase the speed of the semiconductor device 200.

A method of manufacturing the semiconductor device 200 of the present embodiment will be described below.

First, the semiconductor chips 35 to 38 shown in FIG. 2 are prepared. The semiconductor chips 35 to 38 are stacked by the method illustrated in FIGS. 3 and 4, thereby creating the chip laminated body 210. At this time, the semiconductor chip 39 shown in FIG. 4 is not stacked.

Then, the underfill material 34 having the fillet portions 34-1 is introduced to the chip laminated body 210 by the method illustrated in FIGS. 5, 6A, and 6B. At this time, what is positioned at a top layer is the semiconductor chip 38; the surface bump electrodes 56 formed on the principal surface of the semiconductor chip 38 remains exposed without being covered with the underfill material 34.

Then, by the method illustrated in FIGS. 7A and 7B, the chip laminated body 210 is attached onto the dicing tape 86. By the method illustrated in FIGS. 8 and 9, the fillet portions 34-1 of the underfill material 34 are trimmed. As a result, the chip laminated body 220 with the underfill material is formed.

By the method illustrated in FIG. 11, the liquid first sealing resin 14 is supplied to the surface of the wiring mother substrate 93. Then, the semiconductor chip 230 is pushed onto the first sealing resin 14. Accordingly, the surface bump electrodes 231 that are provided on the principal surface of the semiconductor chip 230, and the wire bumps 12 that are provided on the wiring substrate 11 (wiring mother substrate 93) are bonded together. In this manner, on the surface of the wiring substrate 11 (wiring mother substrate 93), the semiconductor chip 230 is flip-chip connected.

Then, to the back surface of the semiconductor chip 230, the liquid third sealing resin 16 is supplied. By the method illustrated in FIG. 12, the chip laminated body 220 with the underfill material is pushed onto the third sealing resin 16. As a result, the back-surface bump electrode 232 that is provided on the back surface of the semiconductor chip 230, and the surface bump electrodes 56 that are formed on the principal surface of the semiconductor chip 38 are bonded together. In this manner, on the back surface of the semiconductor chip 230, the chip laminated body 220 with the underfill material is flip-chip connected.

After that, by the method illustrated in FIGS. 13 to 16, molding and dicing are carried out. As a result, the semiconductor device 200 can be obtained.

### Fourth Embodiment

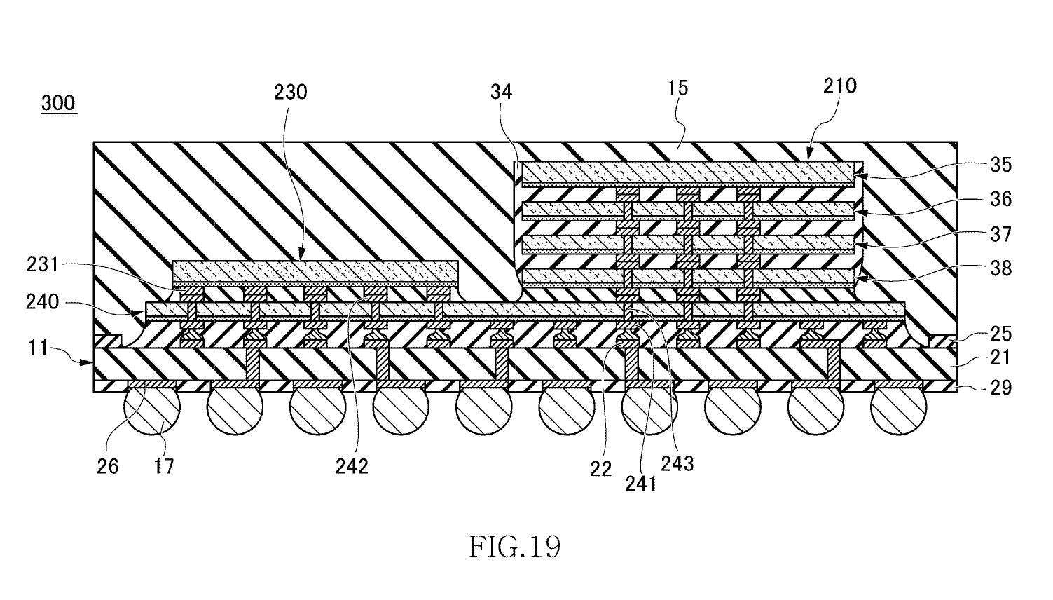

A semiconductor device according to a fourth embodiment of the present invention will be explained with reference to FIG. 19. In FIG. 19, the same components as those of the semiconductor device 200 of the third embodiment are represented by the same reference symbols.

As shown in FIG. 19, the semiconductor device 300 of the present embodiment is different from the semiconductor device 200 of the third embodiment shown in FIG. 18 mainly in that the third semiconductor chip 230 shown in FIG. 18, which is a logic chip, is mounted on a plane different from that of the chip laminated body 220 with the underfill material.

The chip laminated body 220 with the underfill material and the semiconductor chip 230 are flip-chip connected to mutually different planes on a surface of a silicon interposer 240. The silicon interposer 240 is mounted on the wiring substrate 11, and functions as one type of rewiring layer.

The semiconductor device 300 of the present embodiment can achieve the same advantageous effects as the semiconductor device 200 of the above-described third embodiment. Moreover, the chip laminated body 220 with the underfill material and the semiconductor chip 230 are mounted on mutually different planes. Therefore, the chip laminated body 220 with the underfill material and the semiconductor chip 230 can be combined more flexibly. Furthermore, there is no need to provide a penetration electrode on the third semiconductor chip 230, which is a logic chip. Thus, the cost of manufacturing the semiconductor chip 230 can be reduced.

A method of manufacturing the semiconductor device 300 of the present embodiment will be described below.

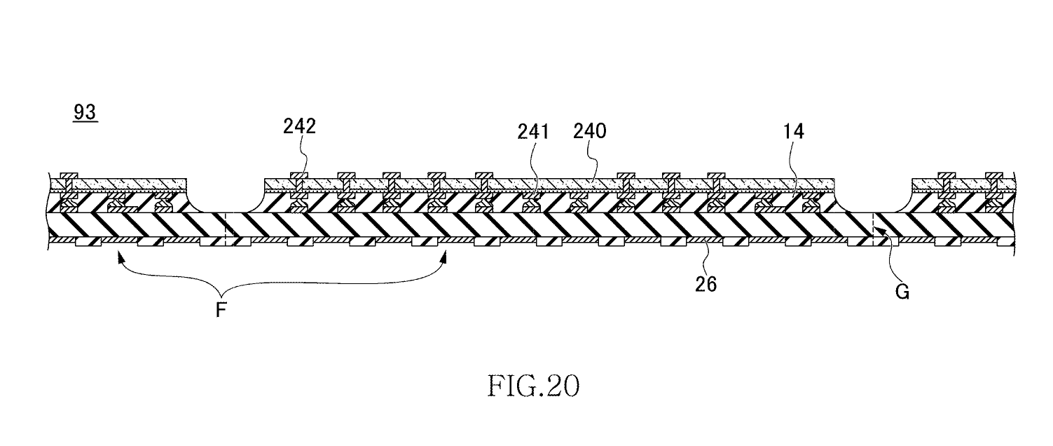

First, as shown in FIG. 20, the wiring mother substrate 93 that has a plurality of wiring substrate formation areas F marked off by dicing lines G is prepared. The wiring substrate formation areas F are areas that will eventually become the wiring substrates 11.

After the liquid first sealing resin 14 is supplied to the wiring substrate formation areas F, the silicon interposer 240 is pressed onto the first sealing resin 14. As a result, the surface bump electrodes 241 that are provided on the principal surface of the silicon interposer 240, and the wire bumps 12 that are provided on the wiring mother substrate 93 are bonded together. In this manner, on the surface of the wiring mother substrate 93, the silicon interposer 240 is flip-chip connected. Moreover, the space between the wiring mother substrate 93 and the silicon interposer 240 is filled with the first sealing resin 14.

The silicon interposer 240 is a substrate made by forming a rewiring layer on a silicon substrate. A plurality of surface bump electrodes 241 that are formed on the surface of the silicon interposer 240, and a plurality of back-surface bump electrodes 242 that are formed on the back surface are electrically connected together via corresponding penetration electrodes 243.

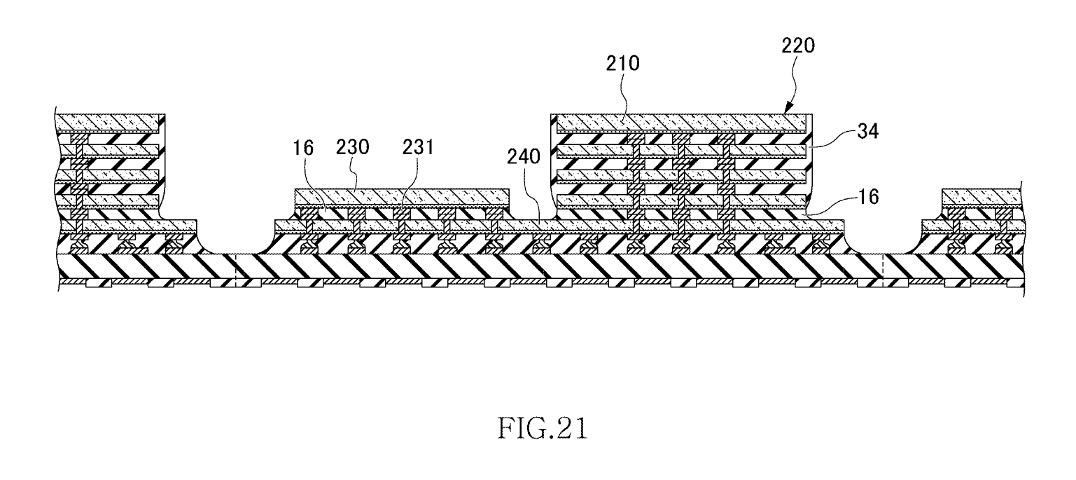

Then, as shown in FIG. 21, onto the silicon interposer 240, the third semiconductor chip 230, which is a logic chip, and the chip laminated body 220 with the underfill material are flip-chip connected.

The above process is performed by supplying the liquid third sealing resin 16 to an area where the third semiconductor chip 230 should be mounted on the back surface of the silicon interposer 240 and an area where the chip laminated body 220 with the underfill material should be mounted, and then pressing the third semiconductor chip 230 and the chip laminated body 220 with the underfill material onto the third sealing resin 16. As a result, to the back surface of the silicon interposer 240, the third semiconductor chip 230 and the chip laminated body 220 with the underfill material are flip-chip connected.

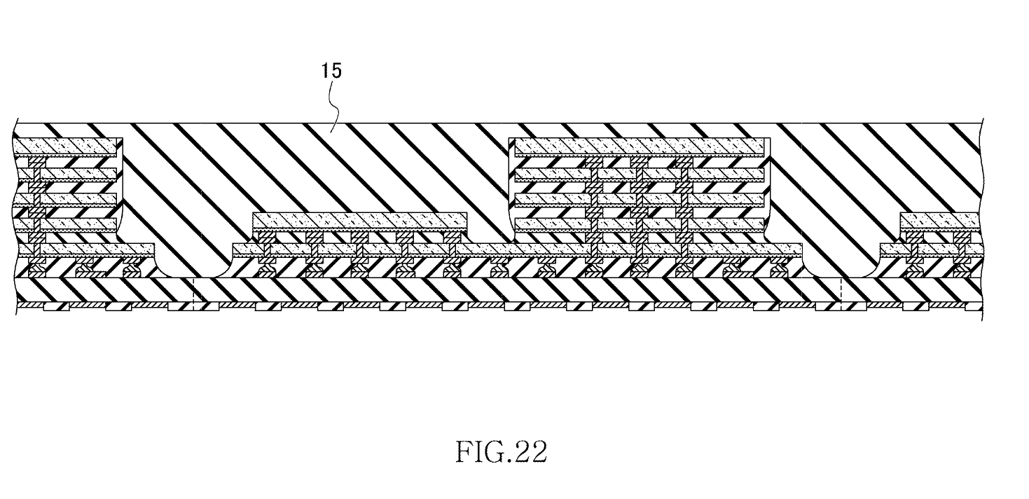

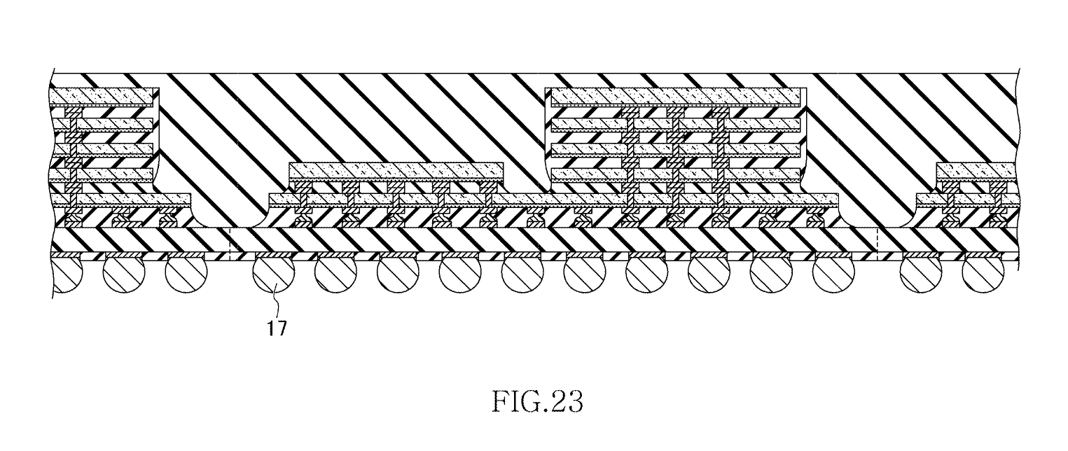

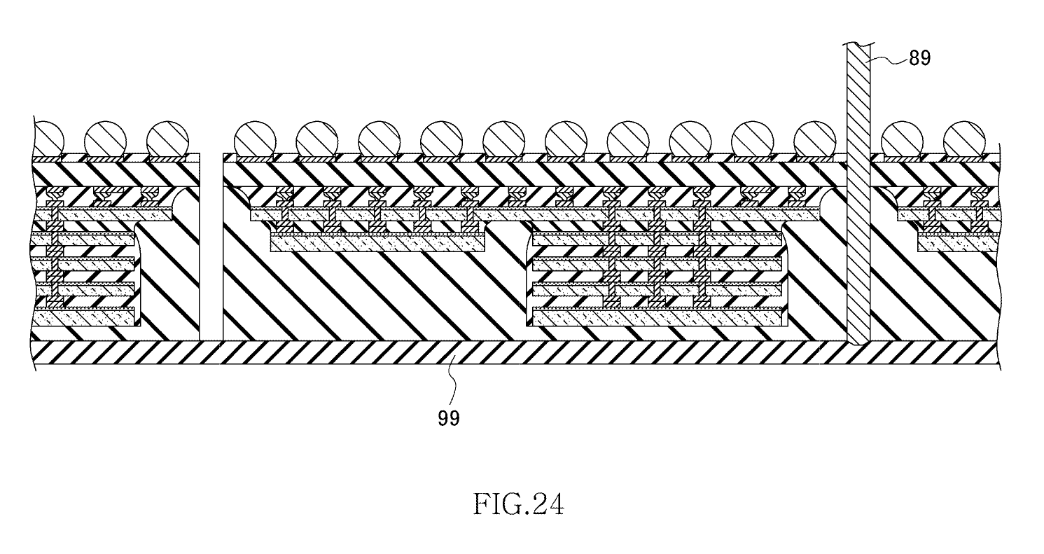

Then, as shown in FIG. 22, after the wiring mother substrate 93 is covered with the second sealing resin 15, the external connection terminals 17, which are solder balls, are mounted as shown in FIG. 23. Then, as shown in FIG. 24, with the wiring mother substrate 93 supported by the dicing tape 99, the dicing blade 89 is used to cut along the dicing lines G, thereby turning a plurality of semiconductor devices 300 into individual pieces.

It is apparent that the present invention is not limited to the above embodiments, but may be modified and changed without departing from the scope and spirit of the invention.

For example, what is described in the first and second embodiments is an example in which one interface semiconductor chip and a plurality (or more specifically, four) of memory semiconductor chips constitute the chip laminated body 33. What is described in the third and fourth embodiments is an example in which a plurality (or more specifically, four) of memory semiconductor chips constitute the chip laminated body 210. However, as long as the chip laminated body 33 or 210 is made by electrically connecting a plurality of semiconductor chips stacked via the penetration electrodes 54, the type of semiconductor chips that make up the chip laminated body 33 or 210 is not limited to the type of semiconductor chips described in the first to fourth embodiments.

What is described in the first and second embodiments is an example in which five semiconductor chips (the first and second semiconductor chips 35 to 39) are stacked to form the chip laminated body 33. However, the number of semiconductor chips that constitute the chip laminated body 33 (or the number of chips stacked) is not limited to five. For example, as in the third and fourth embodiments, four semiconductor chips may be stacked to form the chip laminated body 210.

What is claimed is:

1. A method of manufacturing a semiconductor device comprising:
stacking a plurality of semiconductor chips to form a first chip laminated body;
providing an underfill material to fill gaps between the semiconductor chips so that a fillet portion is formed around the first chip laminated body; and
trimming the fillet portion to form a second chip laminated body.

2. The method of manufacturing the semiconductor device as claimed in claim 1, wherein the trimming is performed such that the second chip laminated body has a trimmed surface that is substantially parallel to a side surface of each of the semiconductor chips.

3. The method of manufacturing the semiconductor device as claimed in claim 1, wherein
each of the semiconductor chips has a rectangle shape, thereby the fillet portion is formed on each of four side walls of the first chip laminated body, and
the trimming is performed such that each of the fillet portions formed on the four side walls are trimmed.

4. The method of manufacturing the semiconductor device as claimed in claim 1, wherein the trimming is performed by cutting or polishing.

5. The method of manufacturing the semiconductor device as claimed in claim 1, further comprising flip-chip mounting the second chip laminated body on a wiring substrate.

6. The method of manufacturing the semiconductor device as claimed in claim 1, further comprising:
flip-chip mounting another semiconductor chip on a wiring substrate such that a principal surface of the wiring substrate faces one surface of the another semiconductor chip; and
flip-chip mounting the second chip laminated body on the other surface of the another semiconductor chip.

7. The method of manufacturing the semiconductor device as claimed in claim 1, further comprising:
flip-chip mounting another semiconductor chip on a first area of a principal surface of a wiring substrate; and
flip-chip mounting the second chip laminated body on a second area that is different from the first area of the principal surface of the wiring substrate.

8. The method of manufacturing the semiconductor device as claimed in claim 7, further comprising providing a silicon interposer between the principal surface of the wiring substrate, and the another semiconductor chip and the second chip laminated body.

9. The method of manufacturing the semiconductor device as claimed in claim 1, wherein
the plurality of the semiconductor chips include a first semiconductor chip and a plurality of second semiconductor chips,
the first semiconductor chip includes a first chip body having one surface that is a substantially flat plane and the other surface on which a first bump electrode is provided,
each of the second semiconductor chips includes a second chip body, the penetration electrode that penetrates through the second chip body, and second bump electrodes provided at both ends of the penetration electrode, and
the stacking is performed by mounting the first semiconductor chip onto a stage of a bonding tool such that the one surface of the first chip body faces the stage, and thereafter sequentially mounting the second semiconductor chips on the first semiconductor chip such that the first bump electrodes, the second bump electrodes and the penetration electrodes are electrically connected to one another.

10. The method of manufacturing the semiconductor device as claimed in claim 9, wherein the providing the underfill material includes:
placing the first chip laminated body such that the one surface of the first chip body faces a sheet material attached to a flat plane of a stage;
dispensing the underfill material in a liquid state to a side wall of the first chip laminated body to seal gaps between the semiconductor chips with a help of capillary phenomenon; and
curing the underfill material to change from the liquid state to a solid state.

11. The method of manufacturing the semiconductor device as claimed in claim 9, wherein one of the second semiconductor chips that is lastly stacked in the stacking is an interface chip, and the other second semiconductor chips and the first semiconductor chip are memory chips.

12. The method of manufacturing the semiconductor device as claimed in claim 9, further comprising flip-chip mounting the second chip laminated body on a wiring substrate having a connection pad.

13. The method of manufacturing the semiconductor device as claimed in claim 12, wherein the flip-chip mounting is performed such that the connection pad of the wiring substrate and the second bump electrode that is exposed from the underfill material are bonded to each other.

14. The method of manufacturing the semiconductor device as claimed in claim 12, further comprising forming a first sealing resin to seal a space between the second chip laminated body and the wiring substrate.

15. The method of manufacturing the semiconductor device as claimed in claim 14, further comprising forming a second sealing resin to seal the second chip laminated body and the first sealing resin on a principal surface of the wiring substrate.

16. The method of manufacturing the semiconductor device as claimed in claim 15, further comprising forming an external connection pad that is electrically connected to the connection pad on a back surface of the wiring substrate.

17. The method of manufacturing the semiconductor device as claimed in claim 1, further comprising:
preparing a logic semiconductor chip having one surface that is a substantially flat plane and the other surface on which third and fourth bump electrodes are provided;
mounting the logic semiconductor chip on a wiring substrate having a connection pad on a principal surface thereof such that the one surface of the logic semiconductor chip faces the principal surface of the wiring substrate;
flip-chip mounting the second chip laminated body on the other surface of the logic semiconductor chip such that the third bump electrode is electrically connected to the second chip laminated body; and
connecting the fourth bump electrode to the connection pad by wire bonding.

18. The method of manufacturing the semiconductor device as claimed in claim 17, further comprising forming a first sealing resin to seal a space between the second chip laminated body and the logic semiconductor chip.

19. The method of manufacturing the semiconductor device as claimed in claim 18, further comprising forming a second sealing resin to seal the second chip laminated body, the first sealing resin, and the logic semiconductor chip on the principal surface of the wiring substrate.

20. The method of manufacturing the semiconductor device as claimed in claim 17, further comprising forming an external connection pad that is electrically connected to the connection pad on a back surface of the wiring substrate.

21. A method for manufacturing a semiconductor device comprising:
stacking a plurality of semiconductor chips to form gaps between adjacent ones of the semiconductor chips;
providing a sealing resin to the gaps between adjacent ones of the semiconductor chips so that a part of the sealing resin protrudes from a side surface of at least one of the semiconductor chips; and
trimming the protruded part of the sealing resin to form a flat surface.

22. The method for manufacturing the semiconductor device as claimed in claim 21, wherein the flat surface is in parallel to the side surface of at least one of the semiconductor chips.
